(19) United States
(12) Patent Application Publication
(10) Pub. No.: US 2024/0397794 A1
(43) Pub. Date: Nov. 28, 2024

(54) DISPLAY DEVICE AND METHOD OF MANUFACTURING SAME

(71) Applicant: Samsung Display Co., LTD., Yongin-si (KR)

(72) Inventors: SANGDUK LEE, Yongin-si (KR); HOIKWAN LEE, Yongin-si (KR)

(21) Appl. No.: 18/648,735

(22) Filed: Apr. 29, 2024

(30) Foreign Application Priority Data
May 23, 2023 (KR) 10-2023-0066471

(51) Int. Cl. H10K 59/80

(52) U.S. Cl. CPC H10K 59/873; H10K 59/8792

(57) ABSTRACT

A display device including a display panel, a polarization unit that includes a first polarization part overlapping the display panel on a plane and a second polarization part extending from the first polarization part and having an outer surface protruding outward from an outer surface of the display panel, and covers the display panel on a plane, an adhesive layer that includes a first adhesive part disposed between the first polarization part and the display panel and a second adhesive part overlapping the second polarization part and is directly disposed on a lower surface of the polarization unit, an adhesive protection member directly disposed on a lower surface of the second adhesive part, a light shielding pattern directly disposed on the polarization unit, and a coated window directly disposed on the polarization unit and the light shielding pattern and including a resin material cured by laser irradiation.

This application claims priority to Korean Patent Application No. 10-2023-0066471, filed on May 23, 2023, and all the benefits accruing therefrom under 35 U.S.C. § 119, the content of which in its entirety is herein incorporated by reference.

### BACKGROUND

### 1. Field

The invention described herein relates to a display device and a method of manufacturing the same, and more particularly, to a display device including an adhesive protection member.

### 2. Description of Related Art

Display devices such as televisions, monitors, smart phones, and tablet personal computers (PCs) that provide images to users include display panels that display images. Various display panels such as liquid crystal display panels, organic light emitting display panels, electro wetting display panels, and electrophoretic display panels have been developed as the display panels. Further, the display device may include a window for protecting the display panel. The window may be attached to the display panel through a lamination process.

### SUMMARY

Embodiments of the invention provide a display device including an adhesive protection member for minimizing exposure of an adhesive layer.

Embodiments of the invention also provide a method of manufacturing the display device including the adhesive protection member for minimizing the exposure of the adhesive layer.

According to an embodiment, a display device includes a display panel including a display area and a non-display area surrounding the display area, a polarization unit that includes a first polarization part overlapping the display panel on a plane and a second polarization part extending from the first polarization part and having an outer surface protruding further outward than an outer surface of the display panel, wherein the second polarization part is disposed on the display panel and covers the display panel on a plane, an adhesive layer that includes a first adhesive part disposed between the first polarization part and the display panel and a second adhesive part overlapping the second polarization part and directly disposed on a lower surface of the polarization unit, an adhesive protection member directly disposed on a lower surface of the second adhesive part, a light shielding pattern directly disposed on the polarization unit and corresponding to the non-display area, and a coated window directly disposed on the polarization unit and the light shielding pattern, wherein the coated window includes a resin material cured by laser irradiation.

In an embodiment, the adhesive protection member may be a part of a protective film of the polarization unit.

In an embodiment, the adhesive protection member may be a resin coated layer.

In an embodiment, the second polarization part may not overlap the display panel.

In an embodiment, one side of the polarization unit may protrude further outward than one side of the display panel, which is adjacent to the one side.

In an embodiment, one side of the polarization unit and one side of the coated window, which is located adjacent to the one side of the polarization unit, may be aligned with each other on a cross section.

In an embodiment, a lower surface of the adhesive layer may be covered by the display panel and the adhesive protection member.

In an embodiment, the light shielding pattern may overlap the second polarization part and a portion of the first polarization part.

In an embodiment, one side of the display panel and one side of the adhesive protection member, which is located adjacent to the one side of the display panel, may be in contact with each other.

In an embodiment, the display panel may include a non-bending area and a bending area extending and bent from a distal end of the non-bending area, wherein the display device may further include a bending protection layer disposed on the display panel and bent together with the bending area.

In an embodiment, the display device may further include a protective panel that includes a barrier layer that shields a light beam and a cushion layer that absorbs an external impact, wherein the protective panel is disposed on a lower surface of the display panel, and protects the display panel.

According to an embodiment, a display device includes a display panel including a display area and a non-display area surrounding the display area, a touch detection panel disposed on the display panel and configured to detect an input signal, a polarization unit that includes a first polarization part overlapping the touch detection panel on a plane and a second polarization part extending from the first polarization part and having an outer surface protruding further outward than an outer surface of the touch detection panel, wherein the second polarization part is disposed on the touch detection panel, and covers the display panel and the touch detection panel on a plane, an adhesive layer that includes a first adhesive part disposed between the first polarization part and the touch detection panel and a second adhesive part overlapping the second polarization part and directly disposed on a lower surface of the polarization unit, an adhesive protection member directly disposed on a lower surface of the second adhesive part, a light shielding pattern directly disposed on the polarization unit and corresponding to the non-display area, and a coated window directly disposed on the polarization unit and the light shielding pattern and including a resin material cured by laser irradiation.

In an embodiment, a lower surface of the adhesive layer may be covered by the touch detection panel and the adhesive protection member.

In an embodiment, the display device may further include a circuit board overlapping the non-display area, wherein the circuit board is bent and has one end disposed on a front surface of the display panel and the other end disposed on a rear surface of the display panel, wherein the display panel may be rigid.

In an embodiment, an outer surface of the adhesive layer, an outer surface of the adhesive protection member, and an outer surface of the polarization unit may be aligned with each other on a cross section.

According to an embodiment, a method of manufacturing a display device includes preparing a display panel including a display area and a non-display area surrounding the display area and a polarization unit having an adhesive layer directly disposed on a lower surface thereof and covering the display panel on a plane, forming an adhesive protection member on a lower surface of the adhesive layer, adhering, to the display panel, a polarization unit including a first polarization part overlapping the display panel on a plane and a second polarization part extending from the first polarization part and having an outer surface protruding further outward than an outer surface of the display panel, forming a light shielding pattern directly disposed on the polarization unit and corresponding to the non-display area, and forming a coated window directly disposed on the polarization unit and the light shielding pattern and including a resin material cured by laser irradiation.

In an embodiment, in the forming of the adhesive protection member on the lower surface of the adhesive layer, a portion of the lower surface of the adhesive layer, which corresponds to the second polarization part, may be resin-coated.

In an embodiment, the forming of the adhesive protection member on the lower surface of the adhesive layer may include attaching a protective film that includes a first protective film part and a second protective film part divided by a cutting line, wherein the protective film is directly disposed on the lower surface of the adhesive layer, and covers a lower surface of the polarization unit, and removing the first protective film part defined inside the cutting line.

In an embodiment, the first protective film may overlap the display panel, and the second protective film may not overlap the display panel.

In an embodiment, the forming of the coated window may include applying a resin material onto the polarization unit, and curing the applied resin material.

### BRIEF DESCRIPTION OF THE FIGURES

The above and other objects and features of the invention will become apparent by describing in detail embodiments thereof with reference to the accompanying drawings.

FIG. 1 is a perspective view of a display device, according to an embodiment.

FIG. 2 is an exploded perspective view of the display device, according to an embodiment.

FIG. 3 is a plan view of a display panel, according to an embodiment.

FIG. 4 is a cross-sectional view of the display device, according to an embodiment.

FIG. 5 is a cross-sectional view of the display device, according to an embodiment.

FIG. 6 is a cross-sectional view of the display device, according to an embodiment.

FIG. 7 is an exploded perspective view of the display device, according to an embodiment.

FIG. 8 is a plan view of a display panel, according to an embodiment.

FIG. 9 is a plan view of a touch detection panel, according to an embodiment.

FIG. 10 is a cross-sectional view of the display device, according to an embodiment.

FIG. 11 is a cross-sectional view of the display device, according to an embodiment.

FIG. 12 is a cross-sectional view of the display device, according to an embodiment.

FIG. 13A is a cross-sectional view of a display device illustrating a portion of a method of manufacturing the display device, according to an embodiment.

FIG. 13B is a cross-sectional view of a display device illustrating a portion of a method of manufacturing the display device, according to an embodiment.

FIG. 13C is a cross-sectional view of a display device illustrating a portion of a method of manufacturing the display device, according to an embodiment.

FIG. 13D is a cross-sectional view of a display device illustrating a portion of a method of manufacturing the display device, according to an embodiment.

FIG. 13E is a cross-sectional view of a display device illustrating a portion of a method of manufacturing the display device, according to an embodiment.

FIG. 14A is a cross-sectional view of a display device illustrating a portion of the method of manufacturing the display device, according to an embodiment.

FIG. 14B is a cross-sectional view of a display device illustrating a portion of the method of manufacturing the display device, according to an embodiment.

FIG. 14C is a cross-sectional view of a display device illustrating a portion of the method of manufacturing the display device, according to an embodiment.

FIG. 14D is a cross-sectional view of a display device illustrating a portion of the method of manufacturing the display device, according to an embodiment.

FIG. 14E is a cross-sectional view of a display device illustrating a portion of the method of manufacturing the display device, according to an embodiment.

FIG. 15A is a cross-sectional view of a display device illustrating a portion of the method of manufacturing the display device, according to an embodiment.

FIG. 15B is a cross-sectional view of a display device illustrating a portion of the method of manufacturing the display device, according to an embodiment.

FIG. 15C is a cross-sectional view of a display device illustrating a portion of the method of manufacturing the display device, according to an embodiment.

FIG. 15D is a cross-sectional view of a display device illustrating a portion of the method of manufacturing the display device, according to an embodiment.

FIG. 16A is a cross-sectional view of a display device illustrating a portion of the method of manufacturing the display device, according to an embodiment.

FIG. 16B is a cross-sectional view of a display device illustrating a portion of the method of manufacturing the display device, according to an embodiment.

FIG. 16C is a cross-sectional view of a display device illustrating a portion of the method of manufacturing the display device, according to an embodiment.

FIG. 16D is a cross-sectional view of a display device illustrating a portion of the method of manufacturing the display device, according to an embodiment.

FIG. 16E is a cross-sectional view of a display device illustrating a portion of the method of manufacturing the display device, according to an embodiment.

FIG. 17A is a cross-sectional view of a display device, illustrating a portion of the method of manufacturing the display device, according to an embodiment.

FIG. 17B is a cross-sectional view of a display device, illustrating a portion of the method of manufacturing the display device, according to an embodiment.

FIG. 17C is a cross-sectional view of a display device, illustrating a portion of the method of manufacturing the display device, according to an embodiment.

FIG. 17D is a cross-sectional view of a display device, illustrating a portion of the method of manufacturing the display device, according to an embodiment.

FIG. 17E is a cross-sectional view of a display device, illustrating a portion of the method of manufacturing the display device, according to an embodiment.

FIG. 18A is a cross-sectional view of a display device illustrating a portion of the method of manufacturing the display device, according to an embodiment.

FIG. 18B is a cross-sectional view of a display device illustrating a portion of the method of manufacturing the display device, according to an embodiment.

FIG. 18C is a cross-sectional view of a display device illustrating a portion of the method of manufacturing the display device, according to an embodiment.

FIG. 18D is a cross-sectional view of a display device illustrating a portion of the method of manufacturing the display device, according to an embodiment.

### DETAILED DESCRIPTION

The invention now will be described more fully hereinafter with reference to the accompanying drawings, in which various embodiments are shown. The invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the present disclosure, the expression that a first component (or area, layer, part, portion, etc.) is “on”, “connected with”, or “coupled to” a second component means that the first component is directly on, connected with, or coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first”, “second”, etc. may be used to describe various components, the components should not be limited by the terms. The terms are only used to distinguish one component from another component. For example, without departing from the scope of the invention, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

The terminology used herein is for the purpose of describing particular embodiments only and is not intended to be limiting. As used herein, “a”, “an,” “the,” and “at least one” do not denote a limitation of quantity, and are intended to include the plural forms as well, unless the context clearly indicates otherwise. Within the Figures and the text of the disclosure, a reference number indicating a singular form of an element may also be used to reference a plurality of the singular element.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical terms and scientific terms) used in the present specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Hereinafter, embodiments of the invention will be described with reference to accompanying drawings.

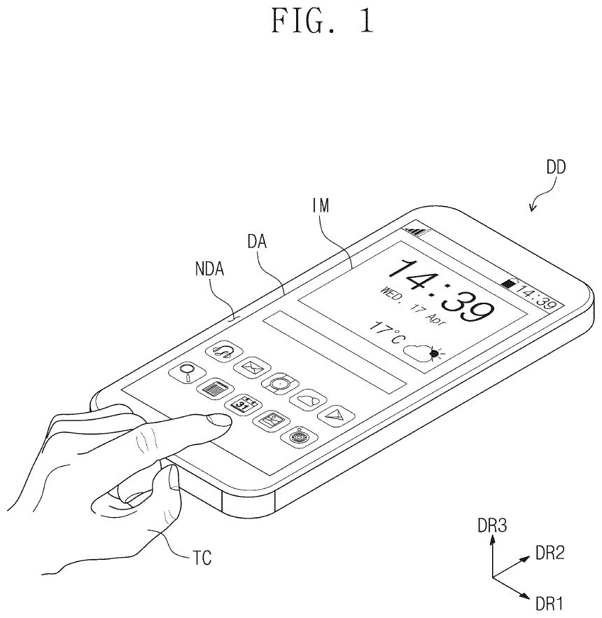

FIG. 1 is a perspective view of a display device DD, according to an embodiment.

Referring to FIG. 1, a portable terminal is illustrated as an example of the display device DD, according to an embodiment. The portable terminal may include a tablet personal computer (PC), a smart phone, a personal digital assistant (PDA), a portable multimedia player (PMP), a game console, a wrist watch-type electronic device, and the like. However, the invention is not limited thereto.

The display device, according to an embodiment, may be used in large-sized electronic apparatuses such as a television and an external billboard as well as small-to-medium sized electronic apparatus such as the PC, a laptop computer, a vehicle navigation unit, and a camera. These are merely presented as embodiments and the display device may be employed with other electronic devices as long as the display devices do not deviate from the concept of the present invention.

In an embodiment, the display device DD may be flexible. The wording “flexible” may mean a property that may be bent and include both a structure that is completely folded and a structure that may be bent by several nanometers. For example, the flexible display device DD may include a curved display device, a foldable display device, a slidable display device, or a rollable display device. However, the invention is not limited thereto, and the display device DD may be rigid.

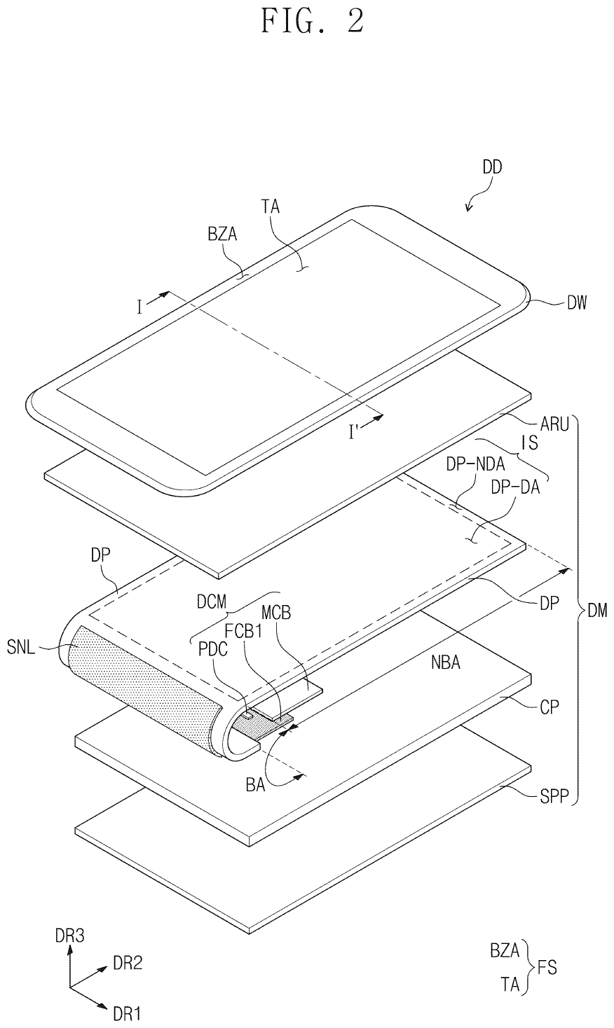

In an embodiment and as illustrated in FIG. 1, a display surface on which an image IM is displayed is parallel to a plane defined by a first direction DR1 and a second direction DR2. The display device DD includes a plurality of areas divided on the display surface. The display surface includes a display area DA on which the image IM is displayed and a non-display area NDA located adjacent to the display area DA. The non-display area NDA may correspond to a bezel area BZA (see FIG. 2). As an example, the display area DA may have a quadrangular shape. The non-display area NDA surrounds the display area DA. Further, although not illustrated, as an example, the display device DD may include a partially curved shape. As a result, one area of the display area DA may have a curved shape.

In an embodiment, a front surface (or an upper surface) and a rear surface (or a lower surface) of each of the members constituting the display device DD may be opposite to each other in a third direction DR3, and a normal direction of each of the front surface and the rear surface may be substantially parallel to the third direction DR3. A separation distance between the front surface and the rear surface defined in the third direction DR3 may correspond to a thickness of a member (or a unit). In the present specification, the wording “on a plan view” may be defined as a state viewed in the third direction DR3. In the present specification, the wording “on a cross section” may be defined as a state viewed in the first direction DR1 or the second direction DR2. Meanwhile, directions indicated by the first to third directions DR1, DR2, and DR3 are relative concepts and may be changed to other directions. In the present specification, the wording “overlap” may refer to a state of overlapping on a plane unless otherwise defined.

In an embodiment, the front surface (or the upper surface or a first surface) and the rear surface (or the lower surface or a second surface) of each of the members are defined based on a direction in which the image IM is displayed. However, the directions indicated by the first to third directions DR1, DR2, and DR3 are relative concepts and may be changed to other directions. Hereinafter, the first to third directions refer to the same reference numerals as those of the directions that are indicated by the first to third directions DR1, DR2, and DR3, respectively.

In an embodiment, the display device DD may detect a touch input TC of a user, which is applied from the outside. The touch input TC of the user includes various types of external inputs such as a portion of a body of the user, a light beam, heat and/or pressure. In an embodiment, it is assumed that the input of the user is a hand of the user applied to the front surface, but this is illustrative, and the touch input TC of the user may be provided in various forms. Further, the display device DD may detect the input of the user applied to a side surface or a rear surface of the display device DD according to a structure of the display device DD, and the invention is not limited to an embodiment.

FIG. 2 is an exploded perspective view of the display device DD, according to an embodiment.

In an embodiment and referring to FIG. 2, the display device DD may include a coated window DW and a display module DM. The coated window DW may be directly disposed on a polarization unit ARU. Here, the wording “directly disposed” may refer to a state of being disposed without a separate adhesive or a separate adhesive layer.

In an embodiment, the coated window DW may provide a front surface FS of the display device DD. The front surface FS of the coated window DW may include a transmissive area TA and the bezel area BZA. The transmissive area TA of the coated window DW may be an optically transparent area. The coated window DW may transmit the image IM provided by a display panel DP through the transmissive area TA, and the user may visually recognize the corresponding image IM (see FIG. 1).

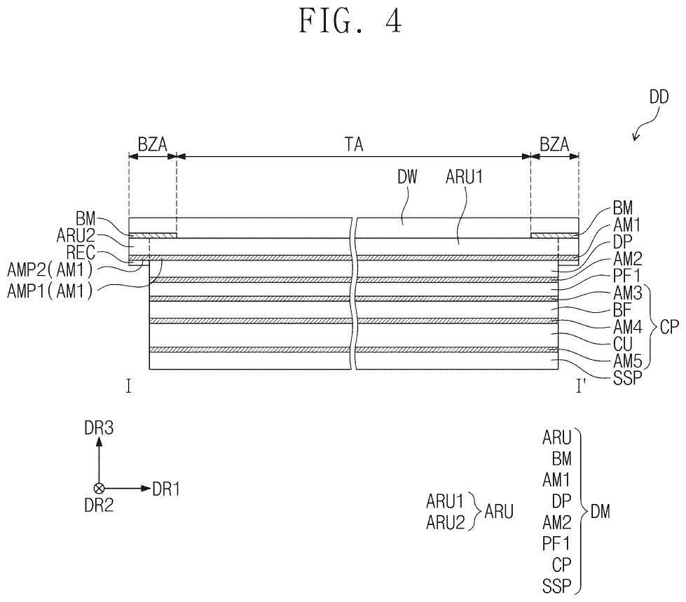

In an embodiment, the bezel area BZA of the coated window DW may overlap a light shielding pattern BM (see FIG. 4), which will be described below. The light shielding pattern BM may include a material that shields a light beam and includes a predetermined color. The bezel area BZA of the coated window DW may prevent one component of the display panel DP disposed to overlap the light shielding pattern BM (see FIG. 4) from being visually recognized from the outside.

In an embodiment, the bezel area BZA may be located adjacent to the transmissive area TA. A shape of the transmissive area TA may be substantially defined by the bezel area BZA. For example, the bezel area BZA may be disposed outside the transmissive area TA and may surround the transmissive area TA. However, this is illustrative, and the bezel area BZA may be located adjacent to only one side of the transmissive area TA or omitted. Further, the bezel area BZA also may be disposed not on a front surface but on a side surface of the display device DD.

In an embodiment, the coated window DW may include an optically transparent insulating material. The coated window DW may include a resin material cured by laser irradiation. The coated window DW may have a single-layer structure or a multi-layer structure. In the display device DD including the coated window DW of the invention, a lamination process is omitted, and thus a process of manufacturing the display device DD may be simplified and costs may be reduced.

In an embodiment, the coated window DW may include a functional coating layer such as an anti-fingerprint layer, an anti-reflective layer, and a hard coating layer. In an embodiment, the coated window DW having a flat shape is illustrated in a display area DP-DA, but the shape of the coated window DW may be modified. Edges of the coated window DW facing each other in the first direction DR1 also may be provided as curved surfaces.

In an embodiment, the display module DM may be disposed on a rear surface of the coated window DW to generate an image. Further, the display module DM may detect the touch input TC (see FIG. 1) of the user.

In an embodiment, the display module DM providing a flat display surface is illustrated, but the shape of the display module DM may be modified. Edges of the display module DM facing each other in the first direction DR1 may be bent from central portions thereof to provide a curved surface.

In an embodiment, the display module DM may include the polarization unit ARU, the display panel DP, a protective panel CP, a support panel SSP, and a driving control module DCM.

In an embodiment, the polarization unit ARU may be disposed between the display panel DP and the coated window DW. The polarization unit ARU may reduce a reflectance of a light beam input from the outside. The polarization unit ARU may include at least one of a phase retarder, a polarizer, a polarization film, and a polarization filter. The polarization unit ARU may be attached to the display panel DP through an adhesive layer. However, the type of the polarization unit ARU is illustrative, and the invention is not limited thereto. For example, the polarization unit ARU may include a color filter.

In an embodiment, the display panel DP may be disposed between the coated window DW and the support panel SSP. The display panel DP may display an image in response to an electrical signal. The display panel DP, according to an embodiment, may be a light emitting display panel, but the invention is not particularly limited thereto. For example, the display panel DP may be an organic light emitting display panel, an inorganic light emitting display panel, an organic-inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. A light emitting layer of the organic-inorganic light emitting display panel may include an organic-inorganic light emitting material. A light emitting layer of the quantum dot light emitting display panel may include a quantum dot and a quantum rod.

In an embodiment, the display panel DP may include a non-bending area NBA and a bending area BA extending and bent from a distal end of the non-bending area NBA. The bending area BA may extend from the non-bending area NBA in an opposite direction to the second direction DR2. The bending area BA may be bent to face a rear surface of the non-bending area NBA.

In an embodiment, the image IM (see FIG. 1) provided by the display device DD may be disposed on a front surface IS of the display panel DP. The front surface IS of the display panel DP may include the display area DP-DA and a non-display area DP-NDA surrounding the display area DP-DA. Here, the display area DP-DA may correspond to the display area DA of FIG. 1, and the non-display area DP-NDA may correspond to the non-display area NDA of FIG. 1. The non-display area DP-NDA may correspond to the bezel area BZA of FIG. 2.

In an embodiment, a bending protection layer SNL may be disposed on the display panel DP and may be bent together with the bending area BA. The bending protection layer SNL may prevent a bent portion of the display panel DP from being damaged by an external impact or prevent foreign substances from flowing thereinto. The bending protection layer SNL illustrated in the drawing is merely illustratively expressed, and the shape of the bending protection layer SNL may be changed as needed.

In an embodiment, the bending protection layer SNL may be disposed on a front surface of the display panel DP and may protect the bent portion of the display panel DP. The bending protection layer SNL may include a plastic film as a base layer. The bending protection layer SNL may include a plastic film including at least one selected from the group consisting of polyether sulphone (PES), polyacrylate (PAR), polyetherimide (PEI), polyethylene naphtholate (PEN), polyethylene terephthalate (PET), polyphenylene sulfide (PPS), polyallylate, polyimide (PI), polycarbonate (PC), poly (arylene ether sulfone), and combinations thereof.

However, in embodiments, a material constituting the bending protection layer SNL is not limited to the plastic resins and may include an organic/inorganic composite material. The bending protection layer SNL may include a porous organic layer and an inorganic material filled in pores of the organic layer. The bending protection layer SNL may include a single-layer structure or a multi-layer structure.

In an embodiment, the display area DP-DA may be an area that is activated according to an electrical signal and displays an image. According to an embodiment, the display area DP-DA of the display panel DP may correspond to the transmissive area TA of the coated window DW. Meanwhile, in the present specification, the wording “area/portion corresponds to area/portion” refers to a state of “overlapping each other” and is not limited to a state of having the same area and/or the same shape.

In an embodiment, the non-display area DP-NDA may be located adjacent to an outer side of the display area DP-DA. For example, the non-display area DP-NDA may surround the display area DP-DA. However, the invention is not limited thereto, and the non-display area DP-NDA may be defined in various shapes.

In an embodiment, the non-display area DP-NDA may be an area in which a driving circuit or driving line for driving elements arranged in the display area DP-DA, various signal lines for providing electrical signals, pads, and the like are arranged. The non-display area DP-NDA of the display panel DP may correspond to the bezel area BZA of the coated window DW. Components of the display panel DP, which are arranged in the non-display area DP-NDA, may be prevented from being visually recognized from the outside by the bezel area BZA.

In an embodiment, the driving control module DCM includes a main circuit board MCB (or a driving circuit board), a first circuit board FCB1 (or a panel flexible circuit board), and a panel driving circuit PDC. The first circuit board FCB1 may be connected to a distal end of the display panel DP to electrically connect the main circuit board MCB and the display panel DP.

In an embodiment, the first circuit board FCB1 may electrically connect the main circuit board MCB and the display panel DP, and the panel driving circuit PDC may be mounted on the first circuit board FCB1. This may be a method of mounting the panel driving circuit PDC in a chip-on-film (COF) method. The panel driving circuit PDC may be implemented as an integrated circuit. Although not separately illustrated, a plurality of passive elements and a plurality of active elements may be mounted on the main circuit board MCB. The main circuit board MCB may be a rigid circuit board or a flexible circuit board, and the first circuit board FCB1 may be a flexible circuit board. The main circuit board MCB may be disposed on a rear surface of the display panel DP.

In an embodiment, the protective panel CP may be disposed on the rear surface of the display panel DP to protect the display panel DP from an impact. The protective panel CP may include a plastic film as a base layer. The protective panel CP may include a single-layer structure or a multi-layer structure.

In an embodiment, the support panel SSP may be disposed on a rear surface of the protective panel CP to support the display panel DP and the protective panel CP. The support panel SSP may be a metal plate having a rigidity greater than or equal to a standard. The support panel SSP may be a stainless steel plate. The support panel SSP may have a black color to shield an external light beam input to the display panel DP.

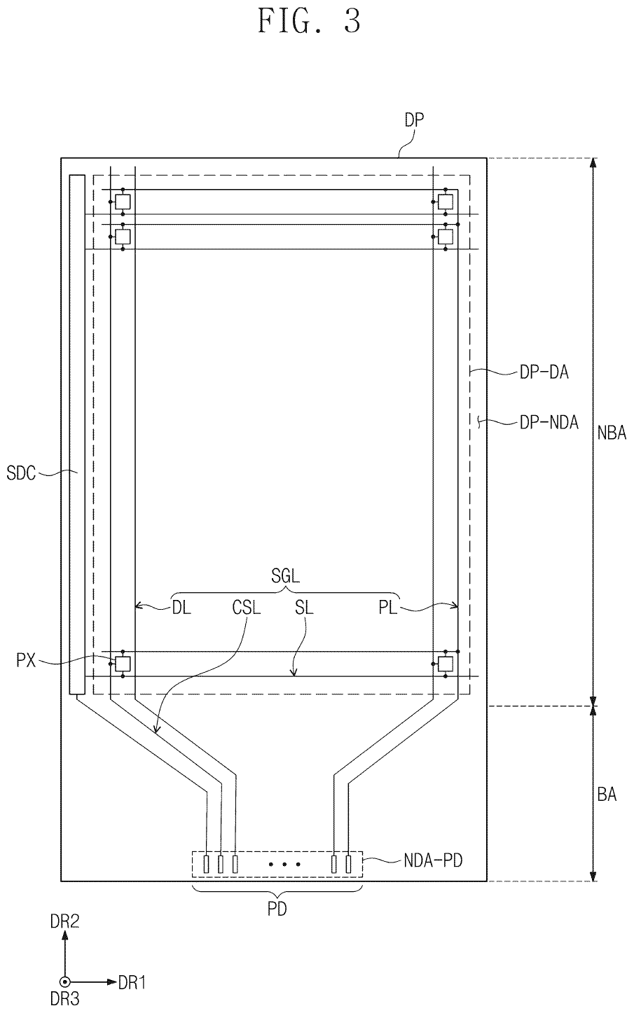

FIG. 3 is a plan view of the display panel DP, according to an embodiment.

FIG. 3 briefly illustrates a signal circuit diagram, according to an embodiment. Further, in FIG. 3, for easy description, some components are omitted.

In an embodiment and referring to FIG. 3, the display panel DP may include the display area DP-DA and the non-display area DP-NDA on a plane. In an embodiment, the non-display area DP-NDA may be defined along an edge of the display area DP-DA. The display area DP-DA and the non-display area DP-NDA of the display panel DP correspond to the display area DA and the non-display area NDA of the display device DD, respectively.

In an embodiment, the display panel DP may include the non-bending area NBA and the bending area BA extending and bent from a distal end of the non-bending area NBA. As illustrated in FIG. 3, in the second direction DR2, the non-bending area NBA may be positioned on an upper side, and the bending area BA may be positioned on a lower side. A lower distal end of the bending area BA may be bent and disposed to face the non-bending area NBA.

In an embodiment, the display panel DP may include a scan driving circuit SDC, a plurality of signal lines SGL (hereinafter, referred to as signal lines), a plurality of signal pads PD (hereinafter, referred to as signal pads), and a plurality of pixels PX (hereinafter, referred to as pixels). The pixels PX are arranged in the display area DP-DA. Each of the pixels PX includes an organic light emitting diode and a pixel driving circuit connected thereto.

In an embodiment, the scan driving circuit SDC generates a plurality of scan signals (hereinafter, scan signals) and sequentially outputs the scan signals to a plurality of scan lines SL (hereinafter, referred to as scan lines), which will be described below. The scan driving circuit SDC may further output another control signal to the driving circuits of the pixels PX.

In an embodiment, the scan driving circuit SDC may include a plurality of thin film transistors formed through the same process as that of the driving circuits of the pixels PX, for example, a low temperature polycrystalline silicon (LTPS) process or a low temperature polycrystalline oxide (LTPO) process.

In an embodiment, the signal lines SGL include the scan lines SL, data lines DL, a power line PL, and a control signal line CSL. The scan lines SL are respectively connected to corresponding pixels PX among the pixels PX, and the data lines DL are respectively connected to corresponding pixels PX among the pixels PX. The power line PL is connected to the pixels PX. The control signal line CSL may provide control signals to the scan driving circuit SDC.

In an embodiment, the signal lines SGL overlap the display area DP-DA and the non-display area DP-NDA. The signal lines SGL may include a pad part and a line part. The line part overlaps the display area DP-DA and the non-display area DP-NDA. The pad part is connected to a distal end of the line part. The pad part is disposed on the non-display area DP-NDA and overlaps a corresponding signal pad among the signal pads PD. An area of the non-display area DP-NDA, in which the signal pads PD are arranged, may be defined as a pad area NDA-PD.

In an embodiment, the line part substantially connected to the pixel PX constitutes most of the signal lines SGL. The line part is connected to transistors (not illustrated) of the pixel PX. The line part may have a single-layer/multi-layer structure, and the line part may be a single body or may include two or more parts. The two or more parts may be arranged on different layers and connected to each other through a contact hole passing through an insulating layer disposed between the two or more parts.

FIG. 4 is a cross-sectional view of the display device DD, according to an embodiment. In more detail, FIG. 4 is a cross-sectional view along line I-I′ of FIG. 2, according to an embodiment.

In an embodiment, although the display panel DP is illustrated as a single layer in FIG. 4, the display panel DP may have a multi-layer structure. The display panel DP may include a base layer, a circuit layer, a light emitting element layer, and an encapsulation layer. In addition, those skilled in the art may understand that other general-purpose components may be further included in the display panel DP.

In an embodiment and referring to FIG. 4, a laminate structure of the display device DD may be identified. The display device DD may include the display module DM and the coated window DW disposed on the display module DM. The display module DM includes the display panel DP, the polarization unit ARU, a first protective layer PF1, the protective panel CP, the support panel SSP, and first to fifth adhesive layers AM1 to AM5, respectively.

In an embodiment, the first to fifth adhesive layers AM1 to AM5, respectively, which will be described below, may be a pressure sensitive adhesive (PSA) film, an optically clear adhesive (OCA) film, or an optically clear resin (OCR). The first adhesive layer AM1 to the fifth adhesive layer AM5 include a photo-curable adhesive material or a heat-curable adhesive material, and the material is not particularly limited. Some of the first adhesive layer AM1 to the fifth adhesive layer AM5 may be omitted.

In an embodiment, the polarization unit ARU may be disposed on an upper surface of the display panel DP. The polarization unit ARU may be disposed between the display panel DP and the coated window DW and may overlap the transmissive area TA and the bezel area BZA. The polarization unit ARU may adhere onto the display panel DP by the first adhesive layer AM1. One side of the polarization unit ARU may protrude outward from one side of the display panel DP located adjacent to the one side. That is, the polarization unit ARU may cover the display panel DP on a plane. A width of the polarization unit ARU in the first direction DR1 may be greater than a width of the display panel DP in the first direction DR1. The polarization unit ARU extending in the first direction DR1 may serve as a base plate for manufacturing the light shielding pattern BM and the coated window DW.

In an embodiment, the one side of the polarization unit ARU may be aligned with one side of the coated window DW disposed adjacent thereto on a cross section. That is, the one side of the polarization unit ARU and the one side of the coated window DW disposed adjacent thereto may be arranged on a straight line on a cross section. Accordingly, separation between the polarization unit ARU and the coated window DW due to an external impact may be minimized.

In an embodiment, the polarization unit ARU may include a first polarization part ARU1 overlapping the display panel DP on a plane and a second polarization part ARU2 extending from the first polarization part ARU1 in the first direction DR1 and an opposite direction to the first direction DR1. An outer surface of the second polarization part ARU2 may protrude outward from an outer surface of the display panel DP, which is disposed adjacent to the outer surface of the second polarization part ARU2. The second polarization part ARU2 may not overlap the display panel DP.

In an embodiment, the first adhesive layer AM1 may be directly disposed on a lower surface of the polarization unit ARU to adhere the polarization unit ARU to the display panel DP. The first adhesive layer AM1 may include a first adhesive part AMP1 overlapping the first polarization part ARU1 and a second adhesive part AMP2 overlapping the second polarization part ARU2. The first adhesive part AMP1 may be disposed between the first polarization part ARU1 and the display panel DP. An upper surface of the first adhesive part AMP1 may be adhered to a lower surface of the first polarization part ARU1 and a lower surface of the first adhesive part AMP1 may be adhered to the upper surface of the display panel DP.

In an embodiment, the second adhesive part AMP2 may be a part of the first adhesive layer AM1, which protrudes outward from the outer surface of the display panel DP. The second adhesive part AMP2 may be disposed between the second polarization part ARU2 and a first adhesive protection member REC. An upper surface of the second adhesive part AMP2 may be adhered to a lower surface of the second polarization part ARU2, and a lower surface of the second adhesive part AMP2 may be adhered to an upper surface of the first adhesive protection member REC.

In an embodiment, the first adhesive protection member REC may be directly disposed on the lower surface of the second adhesive part AMP2. The first adhesive protection member REC may prevent foreign substances from adhering to the lower surface of the second adhesive part AMP2 exposed to the outside. The first adhesive protection member REC may prevent the second adhesive part AMP2 exposed to the outside from adhering to a stage or other structures during a process of manufacturing the display device DD.

In an embodiment, the first adhesive protection member REC may be a resin-coated layer coated on the lower surface of the second adhesive part AMP2. The first adhesive protection member REC may be formed through a separate process of coating the lower surface of the second adhesive part AMP2 with a resin having no adhesion. One side of the first adhesive protection member REC may be in contact with the one side of the display panel DP disposed adjacent to the one side of the first adhesive protection member REC.

In an embodiment, an outer surface of the first adhesive layer AM1, an outer surface of the first adhesive protection member REC, and an outer surface of the polarization unit ARU may be aligned with each other on a cross section. The first adhesive protection member REC may cover the lower surface of the second adhesive part AMP2. A lower surface of the first adhesive layer AM1 may be covered by the display panel DP and the first adhesive protection member REC. Since the first adhesive protection member REC covers the lower surface of the second adhesive part AMP2 exposed to the outside among the lower surface of the first adhesive layer AM1, other structures or foreign substances may be prevented from adhering to the first adhesive layer AM1.

In an embodiment, the light shielding pattern BM may be directly disposed on the polarization unit ARU and may correspond to the non-display area DP-NDA (see FIG. 2). The light shielding pattern BM may define the bezel area BZA. The light shielding pattern BM may overlap a portion of the first polarization part ARU1 and the second polarization part ARU2. The light shielding pattern BM may be disposed adjacent to both sides of the transmissive area TA. An outer surface of the light shielding pattern BM may protrude outward from an outer surface of the display panel DP disposed adjacent thereto. Accordingly, a structure disposed below the light shielding pattern BM may be prevented from being visually recognized from the outside. The light shielding pattern BM may prevent a portion of the light beam generated by the display panel DP from traveling to the outside through not the transmissive area TA but other areas.

In an embodiment, the coated window DW may be directly disposed on the polarization unit ARU and the light shielding pattern BM. The coated window DW may include a resin material cured by laser irradiation. The coated window DW may be formed by applying a resin material such as a resin and curing the resin material. A step corresponding to the light shielding pattern BM may be defined on a lower surface of the coated window DW. An upper surface of the coated window DW may be flat despite a lower surface in which the step is defined. An outer surface of the coated window DW may be aligned with the outer surface of the polarization unit ARU on a cross section. The outer surface of the coated window DW may be aligned with the outer surface of the light shielding pattern BM, the outer surface of the first adhesive layer AM1, and the outer surface of the first adhesive protection member REC on a cross section.

In an embodiment, when the coated window DW is formed by applying the resin material and then curing the resin material, it may be impossible to couple the light shielding pattern BM to the rear surface of the coated window DW. In an embodiment, when the light shielding pattern BM is formed on the expanded polarization unit ARU and then the coated window DW is formed by applying and curing the resin material, the light shielding pattern BM expanded from the display panel DP in the first direction DR1 may be formed. The expanded polarization unit ARU may serve as a base plate for forming the light shielding pattern BM and the coated window DW.

In an embodiment, the first protective layer PF1 may be disposed on a lower surface of the display panel DP to protect the display panel DP from an impact. The first protective layer PF1 may be adhered to the lower surface of the display panel DP by a second adhesive layer AM2. However, the second adhesive layer AM2 may be omitted as needed.

In an embodiment, the protective panel CP may be disposed on the lower surface of the display panel DP. The protective panel CP may protect the display panel DP from an impact transmitted from the lower side.

In an embodiment, the protective panel CP may include a third adhesive layer AM3, a barrier layer BF, a fourth adhesive layer AM4, a cushion layer CU, and a fifth adhesive layer AM5. The barrier layer BF may be adhered to a lower surface of the first protective layer PF1 by the third adhesive layer AM3. The barrier layer BF may have a color with low light transmittance to prevent visual recognition of components under the barrier layer BF.

In an embodiment, the barrier layer BF may include a flexible synthetic resin film. For example, the barrier layer BF may be a film including polyimide (PI), polyethylene terephthalate (PET), or the like. However, the material of the barrier layer BF is not limited thereto, and the barrier layer BF may have various materials as needed.

In an embodiment, the cushion layer CU may be adhered to a lower surface of the barrier layer BF by the fourth adhesive layer AM4. The cushion layer CU may absorb an impact transmitted from a lower portion of the display panel DP. The cushion layer CU may be made of a highly elastic material such as a foam sheet having a plurality of openings.

In an embodiment, the support panel SSP may be disposed below the protective panel CP to support the display panel DP and the protective panel CP. The support panel SSP may be a metal plate having a rigidity greater than or equal to a predetermined standard. For example, the support panel SSP may be a stainless-steel plate. The support panel SSP may have a black color to shield an external light beam input to the display panel DP.

FIG. 5 is a cross-sectional view of the display device DD, according to an embodiment. Since the display device DD of FIG. 5 is the same as the display device DD of FIG. 4 except for the first adhesive protection member REC (see FIG. 4) and a second adhesive protection member APL, the same reference numerals are used for the same components, and a description thereof will be omitted.

In an embodiment and referring to FIG. 5, the second adhesive protection member APL may be directly disposed on the lower surface of the second adhesive part AMP2. The second adhesive protection member APL may prevent foreign substances from adhering to the lower surface of the second adhesive part AMP2 that is exposed to the outside. The second adhesive protection member APL may prevent the second adhesive part AMP2 that is exposed to the outside from adhering to the stage or other structures during a process of manufacturing the display device DD.

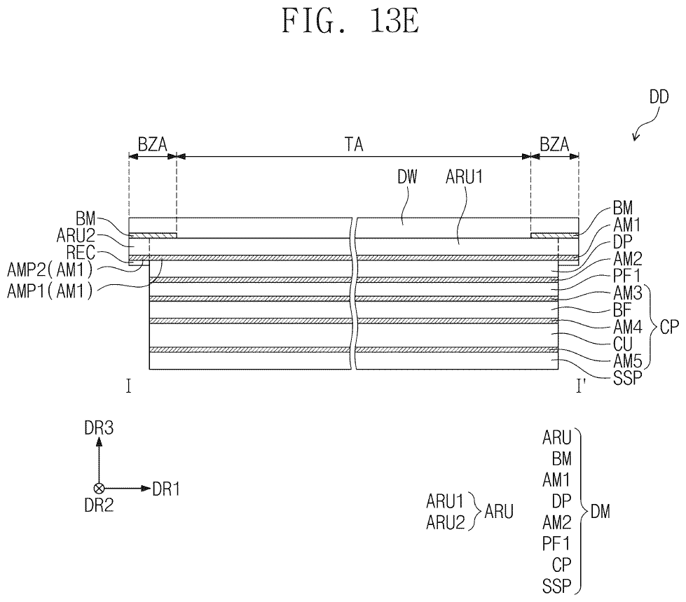

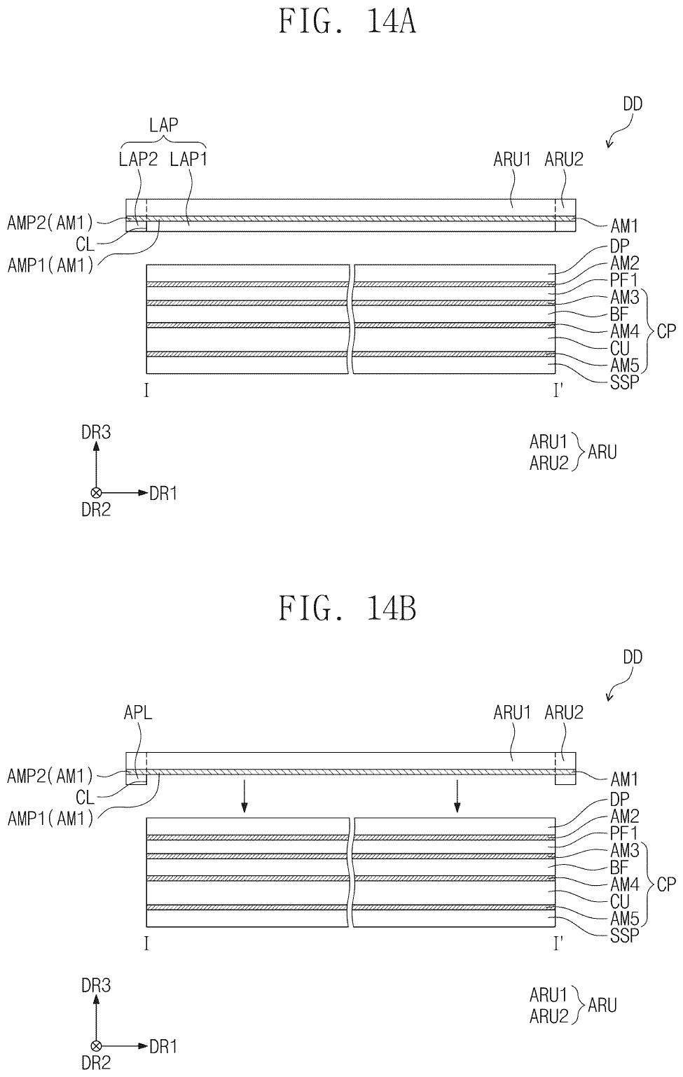

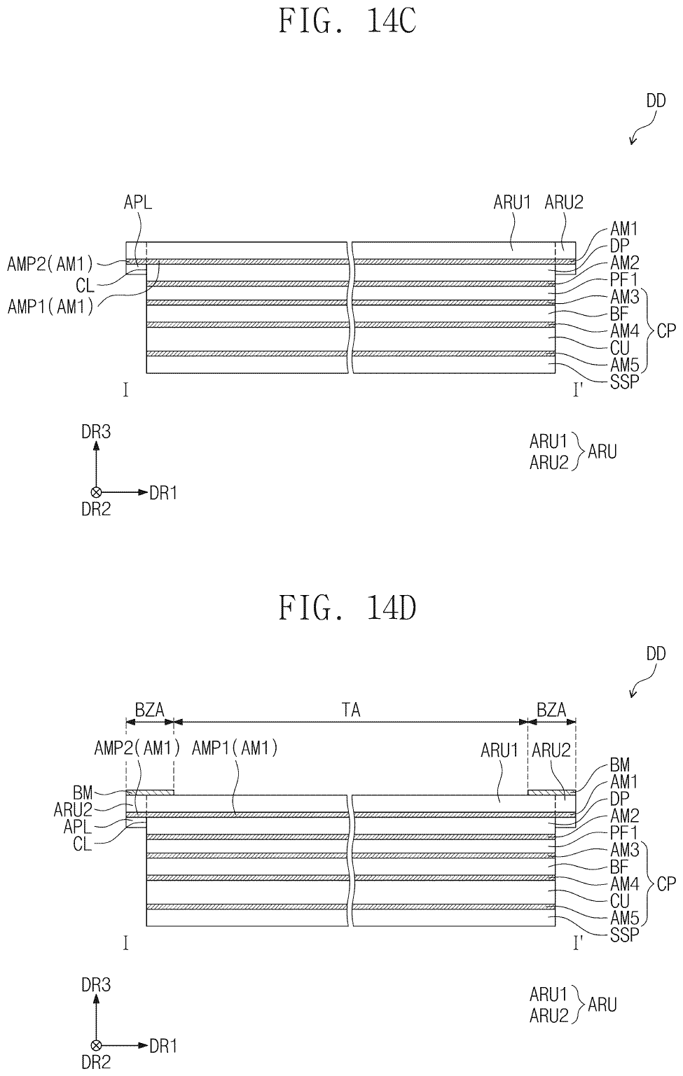

In an embodiment, the second adhesive protection member APL may be a part of a protective film LAP (see FIG. 14A) of the polarization unit ARU. The second adhesive protection member APL may include a material having no adhesive force. The second adhesive protection member APL may include polyethylene terephthalate (PET), polyethylene naphthalate (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polythenylene oxide (MPPO), or the like.

In an embodiment, the outer surface of the first adhesive layer AM1, an outer surface of the second adhesive protection member APL, and the outer surface of the polarization unit ARU may be aligned with each other on a cross section. The second adhesive protection member APL may cover the lower surface of the second adhesive part AMP2. The lower surface of the first adhesive layer AM1 may be covered by the display panel DP and the second adhesive protection member APL. Since the second adhesive protection member APL covers the lower surface of the second adhesive part AMP2 exposed to the outside among the lower surface of the first adhesive layer AM1, other structures or foreign substances may be prevented from adhering to the first adhesive layer AM1.

In an embodiment, the second adhesive protection member APL may be a remaining portion formed by removing a portion of the protective film LAP (see FIG. 14A) of the polarization unit ARU, which corresponds to the display panel DP. This will be described below with reference to FIGS. 14A and 14B.

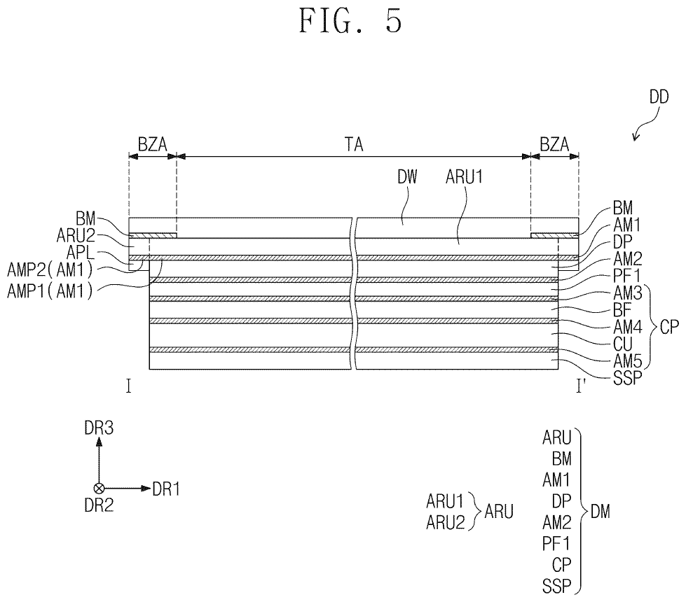

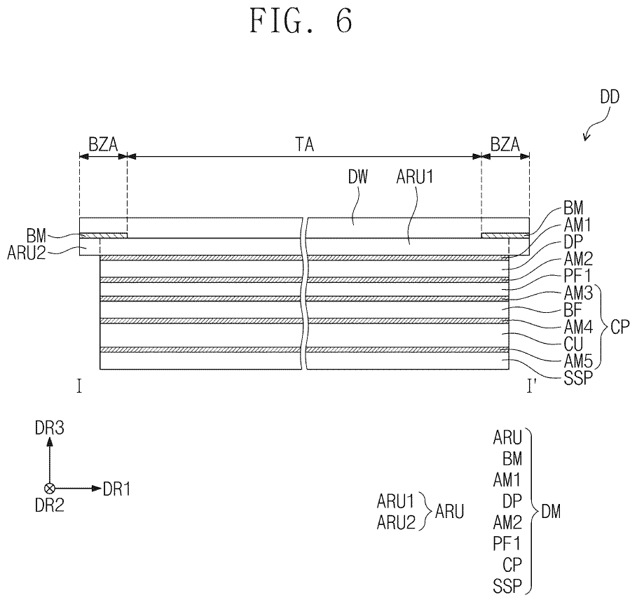

FIG. 6 is a cross-sectional view of the display device DD, according to an embodiment. Since the display device DD of FIG. 6 is the same as the display device DD of FIG. 4 except for the shape of the first adhesive layer AM1 and the absence of the first adhesive protection member REC (see FIG. 4), the same reference numerals are used for the same components, and a description thereof will be omitted.

In an embodiment and referring to FIG. 6, the first adhesive layer AM1 may be directly disposed on a portion of the lower surface of the polarization unit ARU, which overlaps the display panel DP. The first adhesive layer AM1 may not be disposed on a portion of the lower surface of the polarization unit ARU, which does not overlap the display panel DP. Unlike the case of FIG. 4, since the first adhesive layer AM1 does not have a surface exposed to the outside, a separate adhesive protection member may not be required.

In an embodiment, the first adhesive layer AM1 may be formed by laminating an adhesive layer having a size of a portion of the lower surface of the polarization unit ARU, which corresponds to the display panel DP. The first adhesive layer AM1 may be formed by laminating an adhesive layer on an entire surface of the lower surface of the polarization unit ARU and then removing an adhesive at a portion thereof not overlapping the display panel DP through laser irradiation.

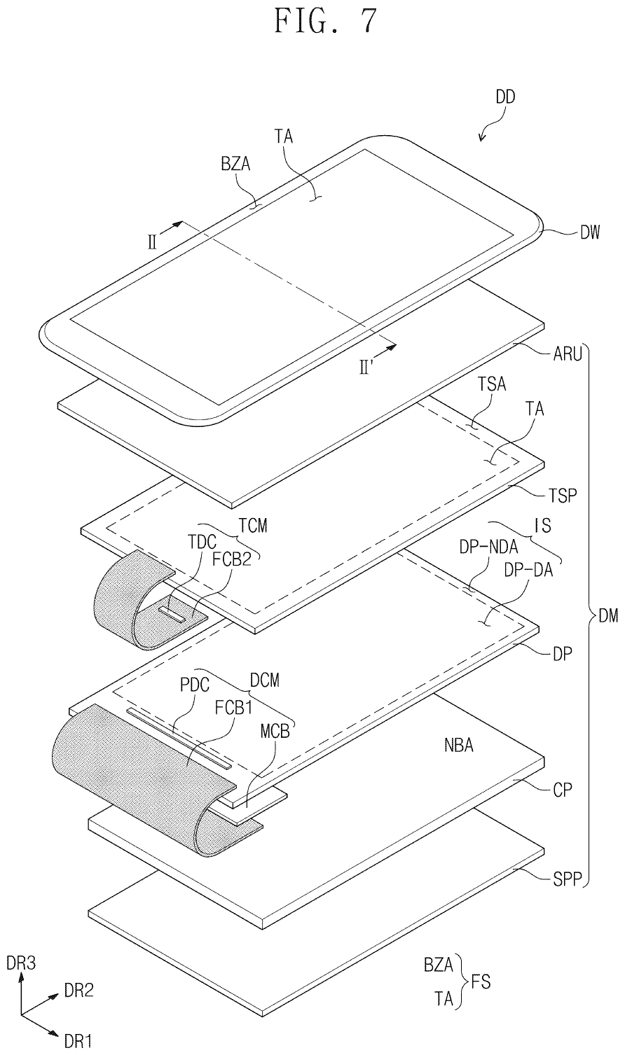

FIG. 7 is an exploded perspective view of the display device DD, according to an embodiment. Here, a description of the same configuration as the configuration described with reference to FIG. 2 will be omitted.

In an embodiment and referring to FIG. 7, the display module DM may include the display panel DP and the driving control module DCM connected to the display panel DP. The display panel DP may not be bent and may be rigid. The driving control module DCM may include the panel driving circuit PDC, the first circuit board FCB1, and the main circuit board MCB. The panel driving circuit PDC may be disposed on the non-display area DP-NDA of the display panel DP. This may be a method of mounting the panel driving circuit PDC in a chip-on-glass (COG) method. In an embodiment, the first circuit board FCB1 may be disposed on the non-display area DP-NDA of the display panel DP and may be bent. The first circuit board FCB1 may be connected to the distal end of the display panel DP to electrically connect the main circuit board MCB and the display panel DP. The first circuit board FCB1 is bent such that one end thereof may be disposed on the front surface of the display panel DP and the other end thereof may be disposed on the rear surface of the display panel DP. The other end of the first circuit board FCB1 and the rear surface of the non-display area DP-NDA may be opposite to each other in the third direction DR3. The main circuit board MCB may be disposed on the rear surface of the display panel DP.

In an embodiment, the display module DM may include a touch detection panel TSP and a touch control unit TCM. The touch detection panel TSP may be disposed between the display panel DP and the polarization unit ARU and connected to a second circuit board FCB2. The touch detection panel TSP may acquire coordinate information of the touch input TC (see FIG. 1) of the user. The touch detection panel TSP may detect various types of inputs provided from the outside of the display device DD. In an embodiment, the touch detection panel TSP may detect an input by the body of the user, but the invention is not limited thereto. For example, the touch detection panel TSP may recognize various types of external inputs such as light, heat, or pressure. Furthermore, the touch detection panel TSP may detect not only an input from contact with a detection surface, but also an input that is disposed close to the detection surface.

In an embodiment, the touch detection panel TSP may be, for example, a capacitive touch panel, an electromagnetic induction type touch panel, or the like. The touch detection panel TSP may include a base layer, detection electrodes, and signal lines connected to the detection electrodes.

In an embodiment, the touch control unit TCM may include the second circuit board FCB2 and a touch driving circuit TDC. The second circuit board FCB2 may electrically connect the main circuit board MCB and the touch detection panel TSP, and the touch driving circuit TDC may be mounted on the second circuit board FCB2. Additionally, like the first circuit board FCB1, the second circuit board FCB2 may also be bent. The touch driving circuit TDC may be implemented as an integrated circuit. The second circuit board FCB2 may be a flexible circuit board.

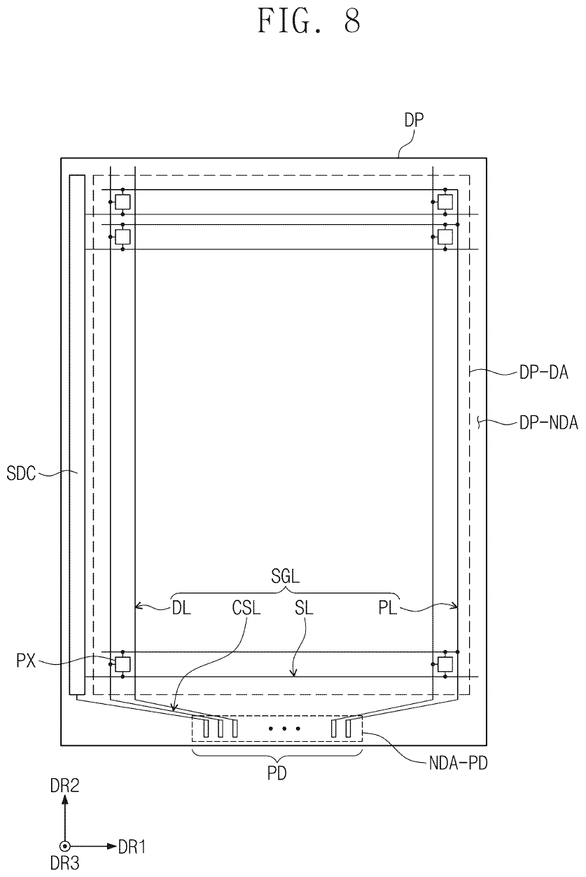

FIG. 8 is a plan view of the display panel DP, according to an embodiment. Hereinafter, a description of the same configuration as the configuration described in FIG. 3 will be omitted.

In an embodiment and referring to FIG. 8, unlike the display panel DP of FIG. 3, the bending area BA (see FIG. 3) may not be present separately. Accordingly, an area of the non-display area DP-NDA of the display panel DP, which is positioned below the display area DP-DA on a plane, may not extend for long in an opposite direction to the second direction DR2. The pad area NDA-PD in which the signal pads PD are arranged may be disposed below the non-display area NDA.

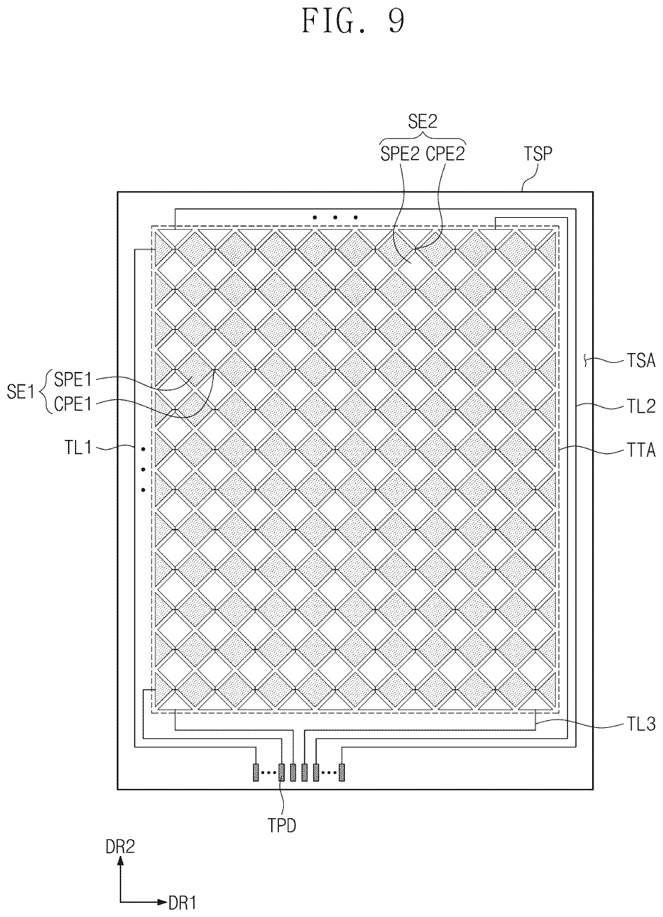

FIG. 9 is a plan view of the touch detection panel TSP, according to an embodiment.

In an embodiment and referring to FIG. 9, the touch detection panel TSP may detect the touch input TC (see FIG. 1) to obtain information on a position or intensity of an external touch input. The touch detection panel TSP may include a touch area TTA and a touch peripheral area TSA on a plane. In an embodiment, the touch peripheral area TSA may be defined along an edge of the touch areas TTA. The touch area TTA and the touch peripheral area TSA of the touch detection panel TSP may correspond to the display area DP-DA and the non-display area DP-NDA of the display device DD illustrated in FIG. 1, respectively.

In an embodiment, the touch detection panel TSP includes a plurality of first detection electrodes SE1, a plurality of second detection electrodes SE2, a plurality of detection lines TL1, TL2, and TL3, and a plurality of detection pads TPD.

In an embodiment, the first detection electrodes SE1 and the second detection electrodes SE2 are disposed in the touch area TTA. The touch detection panel TSP may obtain information on a touch input through a change in a capacitance between the first detection electrodes SE1 and the second detection electrodes SE2.

In an embodiment, each of the first detection electrodes SE1 may extend in the first direction DR1 and may be arranged in the second direction DR2. The first detection electrodes SE1 may include a plurality of first detection patterns SPE1 and a plurality of first connection patterns CPE1.

In an embodiment, the first detection patterns SPE1 constituting one first detection electrode may be spaced apart from each other and arranged in the first direction DR1. In an embodiment, for easy description, the first detection patterns SPE1 are shaded. The first connection patterns CPE1 may be arranged between the first detection patterns SPE1 to connect two adjacent first detection patterns SPE1.

In an embodiment, each of the second detection electrodes SE2 extends in the second direction DR2 and are arranged in the first direction DR1. The second detection electrodes SE2 may include the plurality of second detection patterns SPE2 and a plurality of second connection patterns CPE2.

In an embodiment, the second detection patterns SPE2 constituting one second detection electrode are spaced apart from each other and arranged in the second direction DR2. The second connection patterns CPE2 are arranged between the second detection patterns SPE2 to connect two adjacent second detection patterns SPE2.

In an embodiment, the detection lines TL1, TL2, and TL3 are arranged on the touch peripheral area TSA. The detection lines TL1, TL2, and TL3 may include the first detection lines TL1, the second detection lines TL2, and the third detection lines TL3. The first detection lines TL1 are connected to the first detection electrodes SE1. The second detection lines TL2 are connected to one end of the second detection electrodes SE2.

In an embodiment, the third detection lines TL3 may be connected to the other end of the second detection electrodes SE2. The other end of the second detection electrodes SE2 may be opposite to the one end of the second detection electrodes SE2. According to an embodiment, the second detection electrodes SE2 may be connected to the second detection lines TL2 and the third detection lines TL3. Accordingly, sensitivity according to an area may be uniformly maintained with respect to the second detection electrodes SE2 having a relatively long length as compared to the first detection electrodes SE1. In an embodiment, the third detection lines TL3 may be omitted, and the invention is not limited to this embodiment.

In an embodiment, the detection pads TPD are arranged in the touch peripheral area TSA. The detection pads TPD are respectively connected to the detection lines TL1, TL2, and TL3 to receive an external signal from each of the first detection electrodes SE1 and the second detection electrodes SE2. The detection pads TPD may be connected to the second circuit board FCB2 (see FIG. 8).

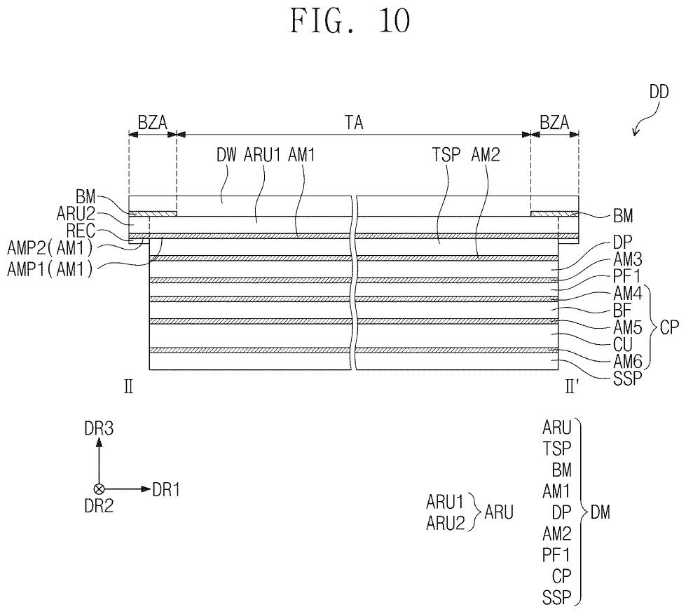

FIG. 10 is a cross-sectional view of the display device DD, according to an embodiment. Since the display device DD of FIG. 10 is the same as the display device DD of FIG. 4 except for the polarization unit ARU and the first adhesive layer AM1, the same reference numerals are used for the same components, and a description thereof will be omitted.

In an embodiment and referring to FIG. 10, the display device DD may include the display panel DP, the polarization unit ARU, the first protective layer PF1, the protective panel CP, the support panel SSP, the touch detection panel TSP, the coated window DW, and the first to sixth adhesive layers AM1 to AM6, respectively. Some of the first to sixth adhesive layers AM1 to AM6, respectively, which will be described below, while others may be omitted.

In an embodiment, the touch detection panel TSP may be disposed on the display panel DP to detect an input signal. The second adhesive layer AM2 adhered between the touch detection panel TSP and the display panel DP may be omitted. The touch detection panel TSP may be disposed between the display panel DP and the polarization unit ARU.

In an embodiment, the polarization unit ARU may be disposed on an upper surface of the touch detection panel TSP. The polarization unit ARU may be disposed between the touch detection panel TSP and the coated window DW and may overlap the transmissive area TA and the bezel area BZA. The polarization unit ARU may adhere onto the touch detection panel TSP by the first adhesive layer AM1. The one side of the polarization unit ARU may protrude outward from one side of the touch detection panel TSP disposed adjacent to the one side. The polarization unit ARU may cover the touch detection panel TSP and the display panel DP on a plane. The polarization unit ARU may be greater than a width of the touch detection panel TSP in the first direction DR1.

In an embodiment, the polarization unit ARU may include the first polarization part ARU1 overlapping the touch detection panel TSP on a plane and the second polarization part ARU2 extending from the first polarization part ARU1 in the first direction DR1 and an opposite direction to the first direction DR1. The outer surface of the second polarization part ARU2 may protrude outward from an outer surface of the touch detection panel TSP, which is disposed adjacent to the outer surface of the second polarization part ARU2. The second polarization part ARU2 may not overlap the touch detection panel TSP.

In an embodiment, the first adhesive layer AM1 may be directly disposed on the lower surface of the polarization unit ARU to adhere the polarization unit ARU to the touch detection panel TSP. The first adhesive layer AM1 may include the first adhesive part AMP1 overlapping the first polarization part ARU1 and the second adhesive part AMP2 overlapping the second polarization part ARU2. The first adhesive part AMP1 may be disposed between the first polarization part ARU1 and the touch detection panel TSP. The upper surface of the first adhesive part AMP1 may be adhered to the lower surface of the first polarization part ARU1, and the lower surface of the first adhesive part AMP1 may be adhered to the upper surface of the touch detection panel TSP. The lower surface of the first adhesive layer AM1 may be covered by the touch detection panel TSP and the first adhesive protection member REC.

In an embodiment, the second adhesive part AMP2 may be a portion of the first adhesive layer AM1, which protrudes outward from the outer surface of the touch detection panel TSP. The second adhesive part AMP2 may be disposed between the second polarization part ARU2 and the first adhesive protection member REC. The upper surface of the second adhesive part AMP2 may be adhered to the lower surface of the second polarization part ARU2, and the lower surface of the second adhesive part AMP2 may be adhered to the upper surface of the first adhesive protection member REC.

In an embodiment, the first adhesive protection member REC may be directly disposed on the lower surface of the second adhesive part AMP2. The first adhesive protection member REC may be a resin-coated layer coated on the lower surface of the second adhesive part AMP2.

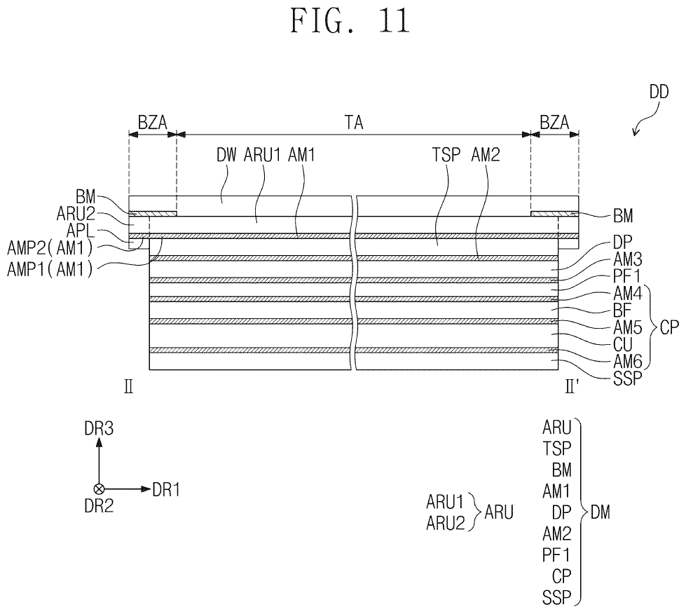

FIG. 11 is a cross-sectional view of the display device DD, according to an embodiment. Since the display device DD of FIG. 11 is the same as the display device DD of FIG. 10 except for the first adhesive protection member REC (see FIG. 10) and the second adhesive protection member APL, the same reference numerals are used for the same components, and a description thereof will be omitted.

In an embodiment and referring to FIG. 11, the second adhesive protection member APL may be directly disposed on the lower surface of the second adhesive part AMP2. The second adhesive protection member APL may prevent foreign substances from adhering to the lower surface of the second adhesive part AMP2 that is exposed to the outside. The second adhesive protection member APL may prevent the second adhesive part AMP2 that is exposed to the outside from adhering to the stage or other structures during a process of manufacturing the display device DD.

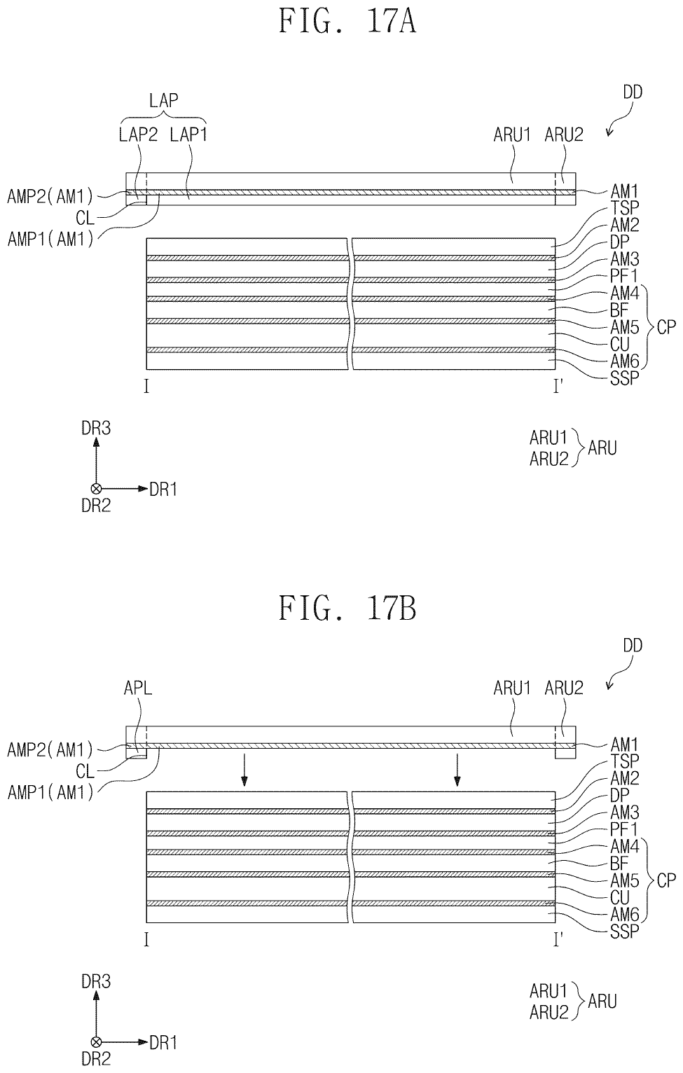

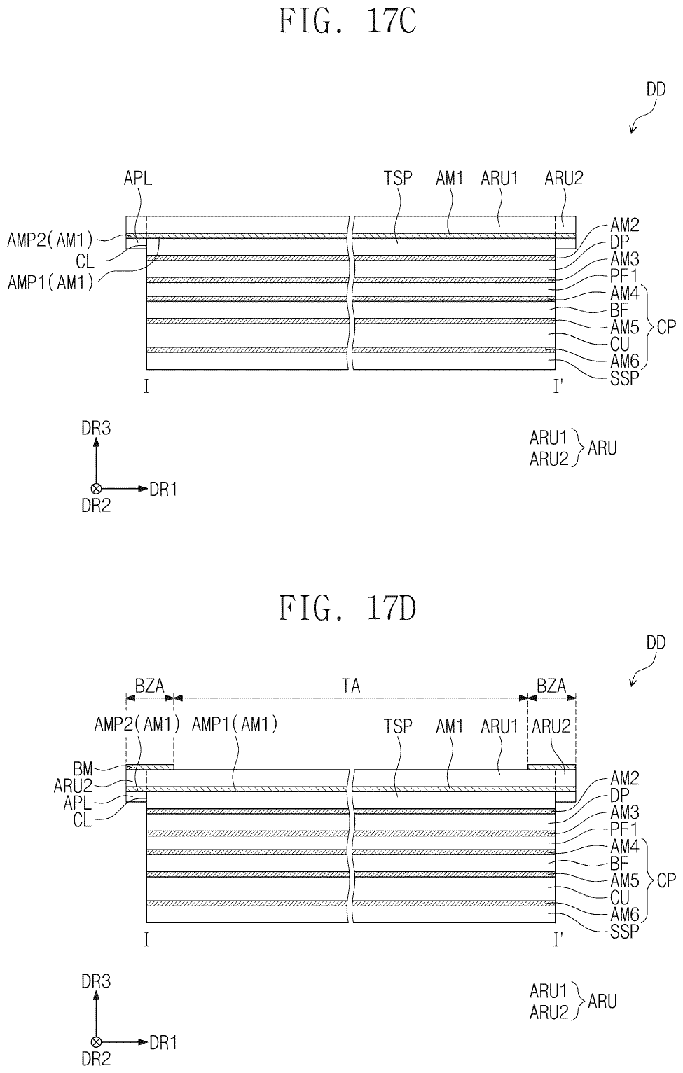

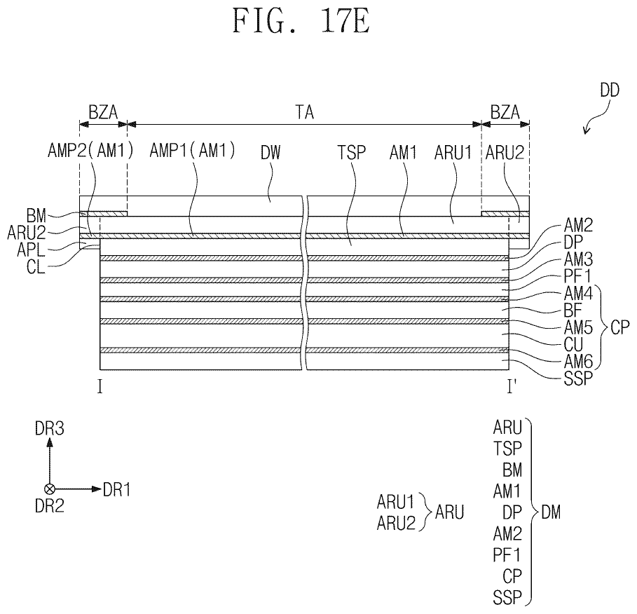

In an embodiment, the second adhesive protection member APL may be a part of the protective film LAP (see FIG. 17A) of the polarization unit ARU. The second adhesive protection member APL may include a material having no adhesive force. The second adhesive protection member APL may include polyethylene terephthalate (PET), polyethylene naphthalate (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polythenylene oxide (MPPO), or the like.

In an embodiment, the outer surface of the first adhesive layer AM1, the outer surface of the second adhesive protection member APL, and the outer surface of the polarization unit ARU may be aligned with each other on a cross section. The second adhesive protection member APL may cover the lower surface of the second adhesive part AMP2. The lower surface of the first adhesive layer AM1 may be covered by the touch detection panel TSP and the second adhesive protection member APL. Since the second adhesive protection member APL covers the lower surface of the second adhesive part AMP2 exposed to the outside among the lower surface of the first adhesive layer AM1, other structures or foreign substances may be prevented from adhering to the first adhesive layer AM1.

In an embodiment, the second adhesive protection member APL may be a remaining portion formed by removing a portion of the protective film LAP (see FIG. 17A) of the polarization unit ARU, which corresponds to the display panel DP. This will be described below with reference to FIGS. 17A and 17B.

FIG. 12 is a cross-sectional view of the display device DD, according to an embodiment. Since the display device DD of FIG. 12 is the same as the display device DD of FIG. 10 except for the shape of the first adhesive layer AM1 and the absence of the first adhesive protection member REC (see FIG. 10), the same reference numerals are used for the same components, and a description thereof will be omitted.

In an embodiment and referring to FIG. 12, the first adhesive layer AM1 may be directly disposed on a portion of the lower surface of the polarization unit ARU, which overlaps the touch detection panel TSP. The first adhesive layer AM1 may not be disposed on a portion of the lower surface of the polarization unit ARU, which does not overlap the touch detection panel TSP. Unlike the embodiment of FIG. 10, since the first adhesive layer AM1 does not have a surface exposed to the outside, a separate adhesive protection member may not be required.

In an embodiment, the first adhesive layer AM1 may be formed by laminating an adhesive layer having a size of a portion of the lower surface of the polarization unit ARU, which corresponds to the touch detection panel TSP. The first adhesive layer AM1 may be formed by laminating an adhesive layer on the entire surface of the lower surface of the polarization unit ARU and then removing an adhesive at a portion thereof not overlapping the touch detection panel TSP through laser irradiation.

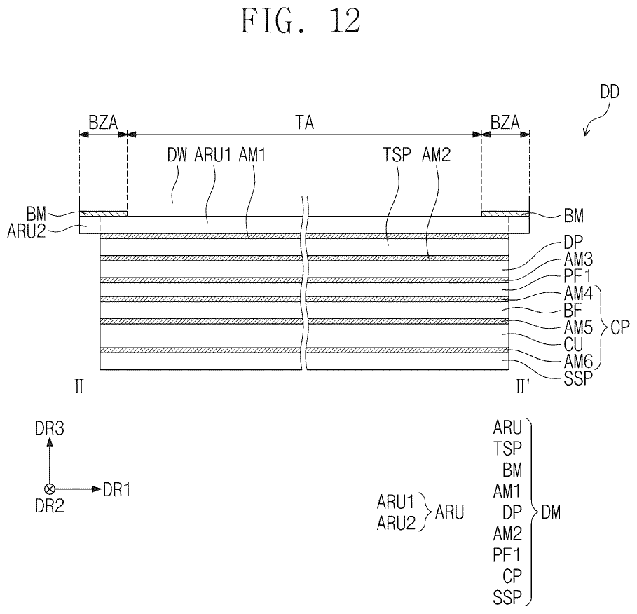

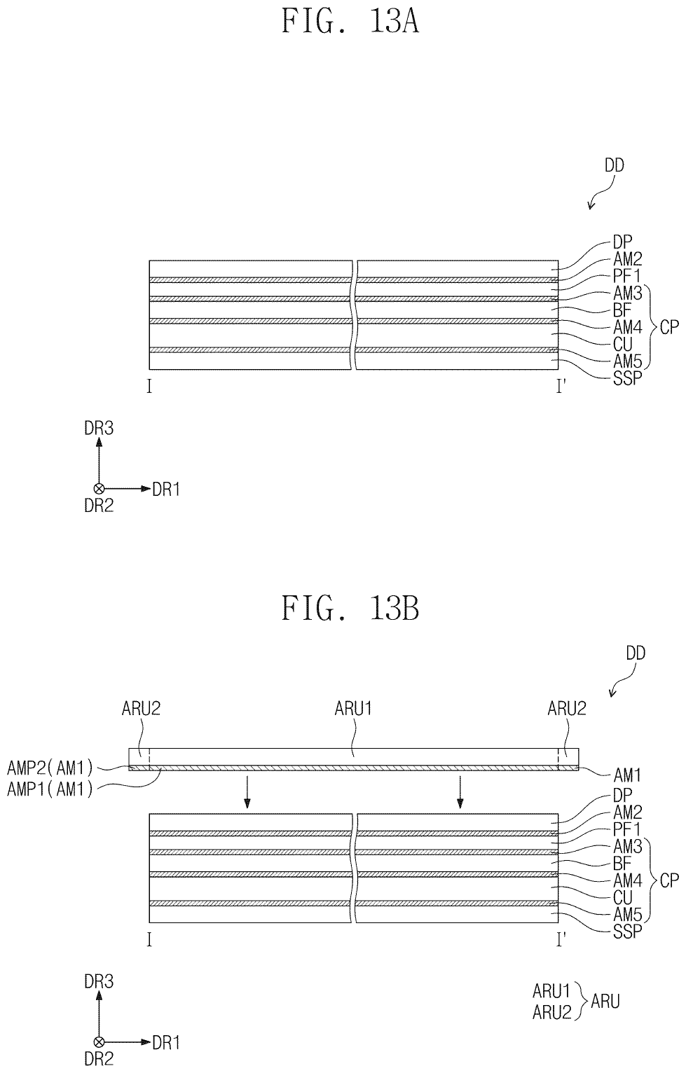

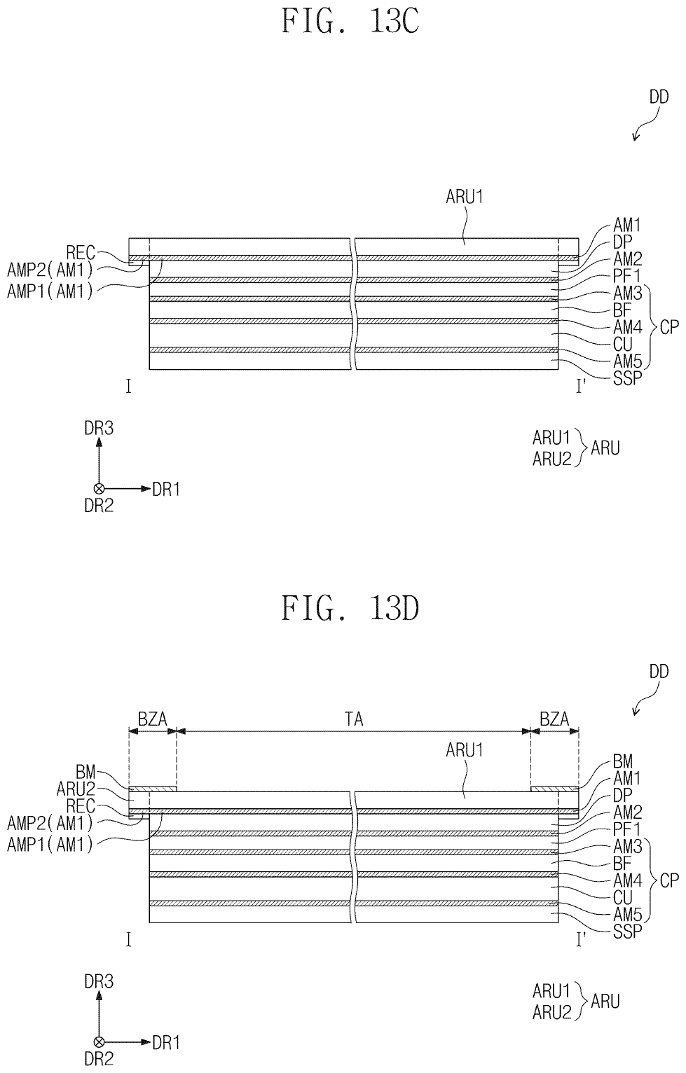

FIGS. 13A to 13E are cross-sectional views illustrating a portion of a method of manufacturing the display device DD, according to an embodiment. FIGS. 13A to 13E are cross-sectional views illustrating a portion of the method of manufacturing the display device DD of FIG. 4. The same reference numerals are used for the components described in FIG. 4, and a description thereof will be omitted.

In an embodiment and referring to FIGS. 13A and 13B, the display panel DP including the display area DP-DA (see FIG. 3) and the non-display area DP-NDA (see FIG. 3) may be prepared. The polarization unit ARU having the first adhesive layer AM1 directly disposed on the lower surface thereof and covering the display panel DP on a plane may be prepared. The polarization unit ARU including the first polarization part ARU1 and the second polarization part ARU2 may be adhered to the upper surface of the display panel DP.

In an embodiment and referring to FIG. 13C, the first adhesive protection member REC may be formed on the lower surface of the first adhesive layer AM1. The first adhesive protection member REC may be formed on the lower surface of the second adhesive part AMP2 of the lower surface of the first adhesive layer AM1, which corresponds to the second polarization part ARU2. In this case, a resin having no adhesive force may be applied to the lower surface of the second adhesive part AMP2. The coated resin layer may prevent the lower surface of the second adhesive part AMP2 from being exposed to the outside. FIG. 13C illustrates that the first adhesive protection member REC is coated after the polarization unit ARU is adhered to the display panel DP, but the first adhesive protection member REC may be coated before the polarization unit ARU is adhered to the display panel DP. For example, after the first adhesive protection member REC is coated on the lower surface of the second adhesive part AMP2 of FIG. 13B, the polarization unit ARU may be adhered to the display panel DP.

In an embodiment and referring to FIG. 13D, the light shielding pattern BM may be formed on the polarization unit ARU. The light shielding pattern BM may correspond to the non-display area DP-NDA (see FIG. 3). The light shielding pattern BM may be formed by applying a light shielding material on an upper surface of the polarization unit ARU and then curing the light shielding material using a light beam generated by an exposure device. The light shielding pattern BM may be directly disposed on the polarization unit ARU. The light shielding material may be a black resin that shields a light beam. In this way, when the light shielding pattern BM is formed, the polarization unit ARU may serve as a base plate onto which the light shielding material is applied.

In an embodiment and referring to FIG. 13E, the coated window DW may be formed on the polarization unit ARU and the light shielding pattern BM. The coated window DW may be formed by applying a coating solution including a resin material onto the polarization unit ARU and the light shielding pattern BM and curing the applied coating solution. A laser beam generated by a separate exposure device may be used to cure the applied coating solution. In this way, as the coated window DW is formed, a manufacturing process is simplified due to omission of a separate lamination process and omission of a process of forming an optical clear adhesive (OCA) for adhesion of a window, and thus process reliability may be improved and costs may be reduced.

FIGS. 14A to 14E are cross-sectional views illustrating a portion of the method of manufacturing the display device DD, according to an embodiment. FIGS. 14A to 14E are cross-sectional views illustrating a portion of the method of manufacturing the display device DD of FIG. 5, according to an embodiment. The same reference numerals are used for the components described in FIG. 5, and a description thereof will be omitted.

In an embodiment and referring to FIG. 14A, the display panel DP and the polarization unit ARU having the first adhesive layer AM1 disposed on the lower surface thereof and covering the display panel DP on a plane may be prepared. The protective film LAP may be attached onto the lower surface of the first adhesive layer AM1. The protective film LAP may be directly disposed on the lower surface of the first adhesive layer AM1 and cover the lower surface of the polarization unit ARU. The protective film LAP may include a first protective film part LAP1 and a second protective film part LAP2 divided by a cutting line CL. Here, the first protective film part LAP1 may overlap the display panel DP, and the second protective film part LAP2 may not overlap the display panel DP.

In an embodiment, the protective film LAP may have sufficient impact resistance and sufficient heat resistance to protect the polarization unit ARU. The protective film LAP may include polyethylene terephthalate (PET), polyethylene naphthalate (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polythenylene oxide (MPPO), or the like.

In an embodiment and referring to FIGS. 14B and 14C, the first protective film part LAP1 (see FIG. 14A) defined inside the cutting line CL may be removed. The second protective film part LAP2 (see FIG. 14A) from which the first protective film part LAP1 (see FIG. 14A) is removed may serve as the second adhesive protection member APL. In this way, the protective film LAP (see FIG. 14A) previously used to protect the polarization unit ARU may be processed and thus used as the second adhesive protection member APL. The polarization unit ARU from which the first protective film part LAP1 (see FIG. 14A) is removed may be adhered to the display panel DP.

In an embodiment and referring to FIG. 14D, the light shielding pattern BM may be formed on the polarization unit ARU. The light shielding pattern BM may be formed by applying a light shielding material on the upper surface of the polarization unit ARU and then curing the light shielding material using a light beam generated by an exposure device.

In an embodiment and referring to FIG. 14E, the coated window DW may be formed on the polarization unit ARU and the light shielding pattern BM. The coated window DW may be formed by applying a coating solution including a resin material onto the polarization unit ARU and the light shielding pattern BM and curing the applied coating solution.

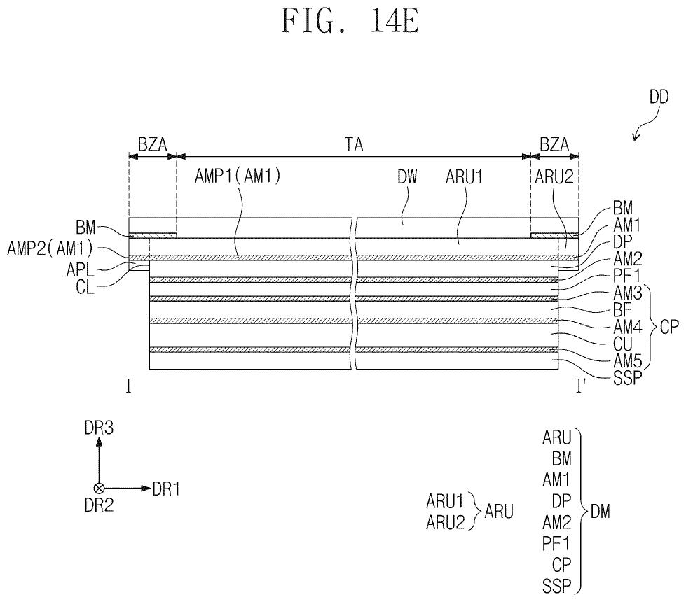

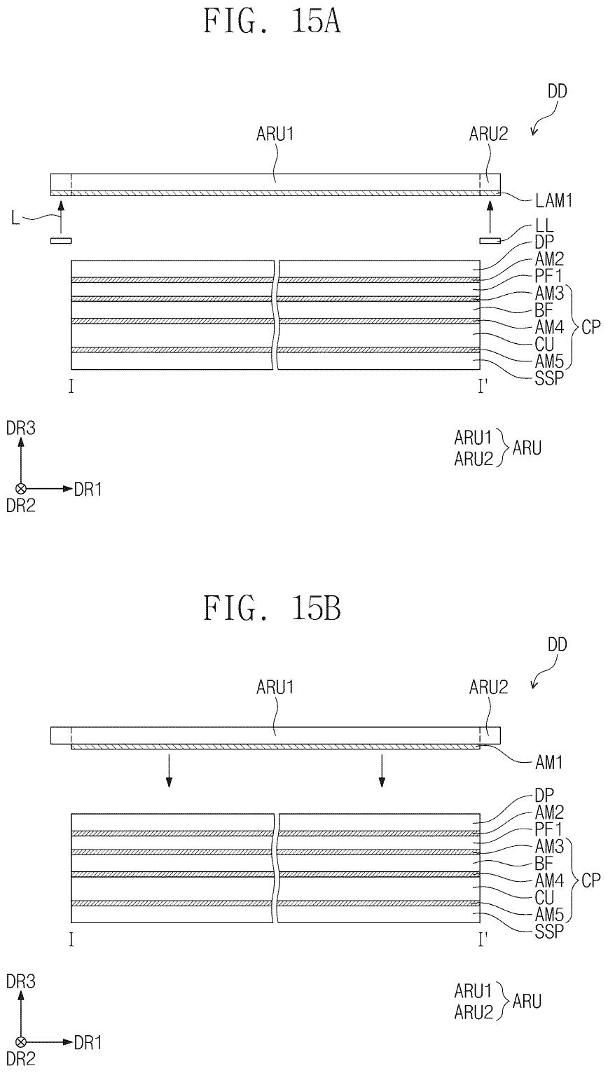

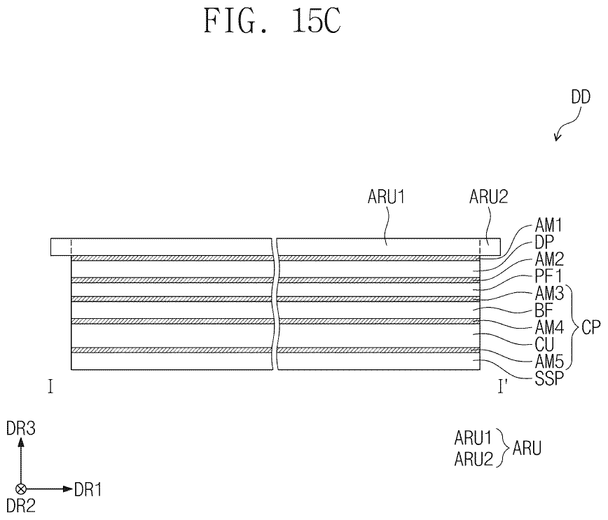

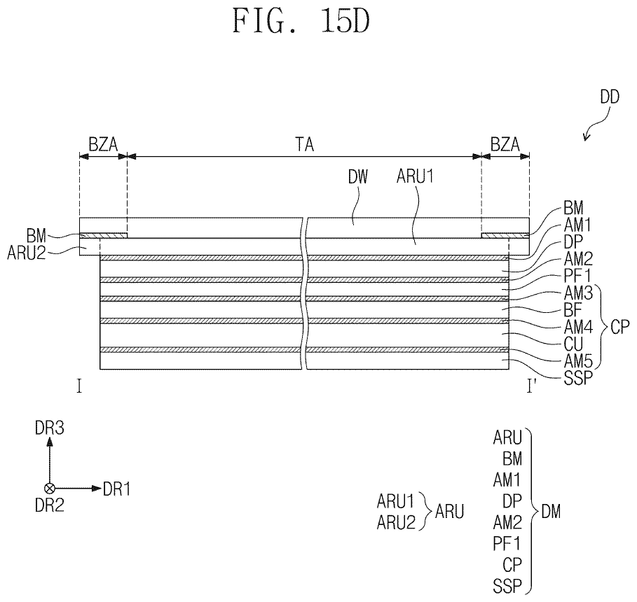

FIGS. 15A to 15D are cross-sectional views illustrating a portion of the method of manufacturing the display device DD, according to an embodiment. FIGS. 15A to 15D are cross-sectional views illustrating a portion of the method of manufacturing the display device DD of FIG. 6, according to an embodiment. The same reference numerals are used for the components described in FIG. 6, and a description thereof will be omitted.

In an embodiment and referring to FIG. 15A, the display panel DP and the polarization unit ARU having a preliminary first adhesive layer LAM1 directly disposed on the lower surface thereof and covering the display panel DP on a plane may be prepared. A portion of the preliminary first adhesive layer LAM1, which does not overlap the display panel DP and which corresponds to the second polarization part ARU2, may be removed using a laser beam “L” generated by an exposure device LL. However, as illustrated in FIG. 15A, the preliminary first adhesive layer LAM1 is disposed on the lower side of the polarization unit ARU, the portion of the preliminary first adhesive layer LAM1 is not removed using the laser beam “L”, and the first adhesive layer AM1 (see FIG. 15B) having a size corresponding to the display panel DP may also be laminated on the lower surface of the polarization unit ARU. In this case, an operation of irradiating the laser beam “L” of FIG. 15A may be omitted.

Further, in an embodiment, the portion of the preliminary first adhesive layer LAM1 is not removed using the laser beam “L”, but is attached to the upper surface of the touch detection panel TSP, and then is removed using the laser beam “L” generated by the exposure device LL, so that the first adhesive layer AM1 (see FIG. 15B) may be formed.

In an embodiment and referring to FIGS. 15B and 15C, the first adhesive layer AM1 of which a portion corresponding to the second polarization part ARU2 is removed may be adhered to the upper surface of the display panel DP. The first adhesive layer AM1 may be disposed only between the first polarization part ARU1 and the display panel DP and may not be exposed to the outside.

In an embodiment and referring to FIG. 15D, the light shielding pattern BM and the coated window DW may be formed on the polarization unit ARU. The light shielding pattern BM and the coated window DW may be formed in the same manner as that described with reference to FIGS. 13D and 13E.

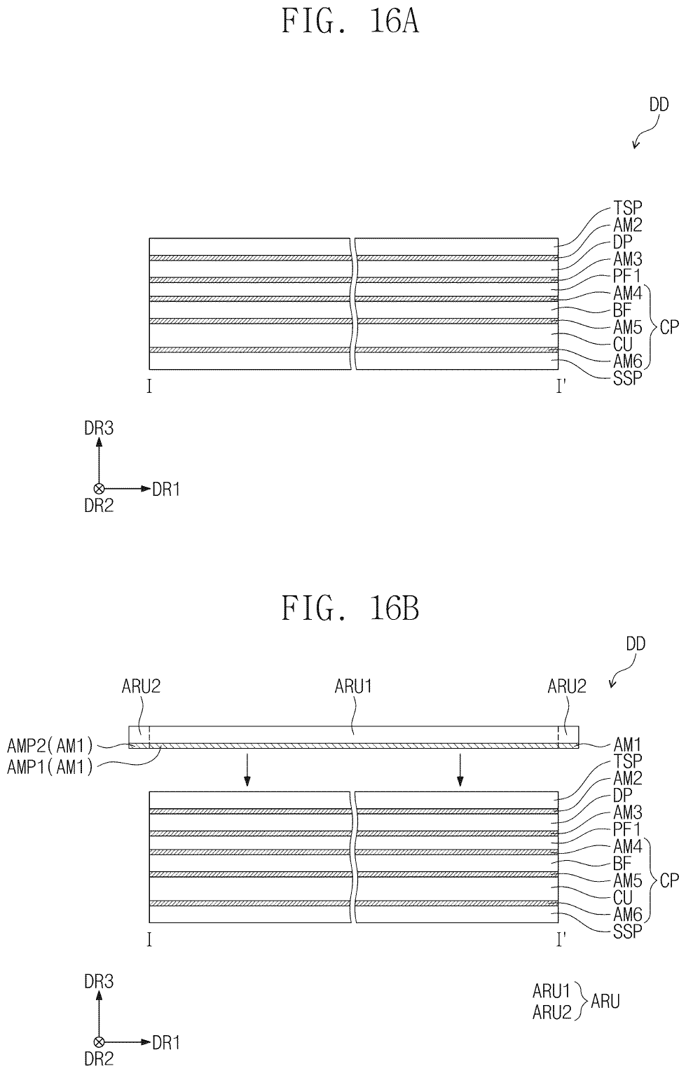

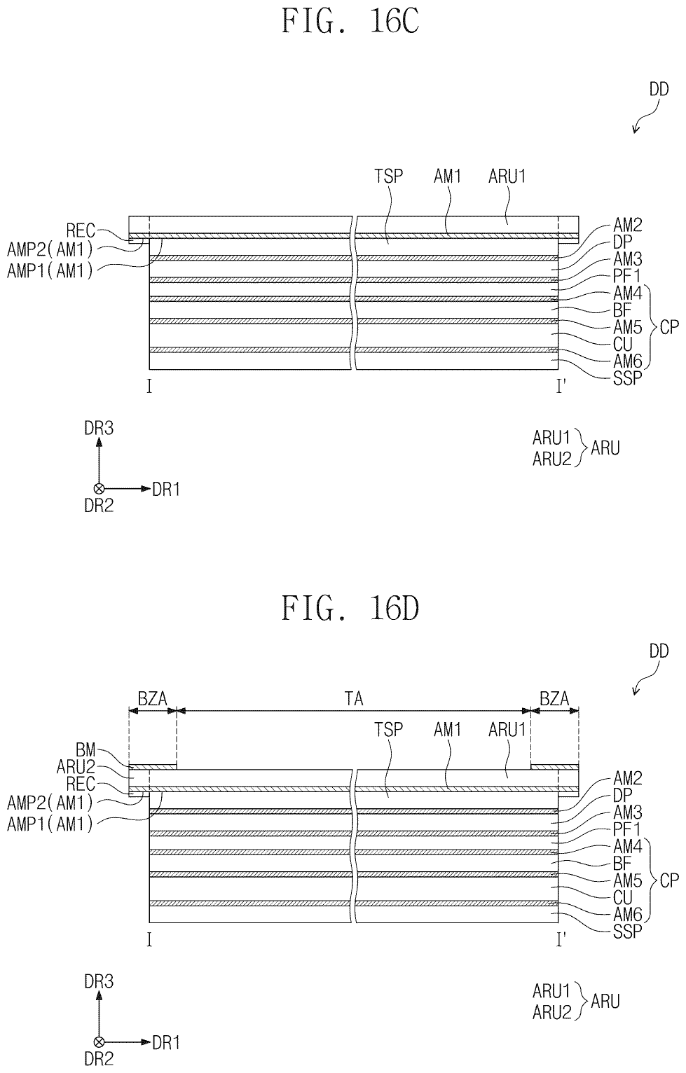

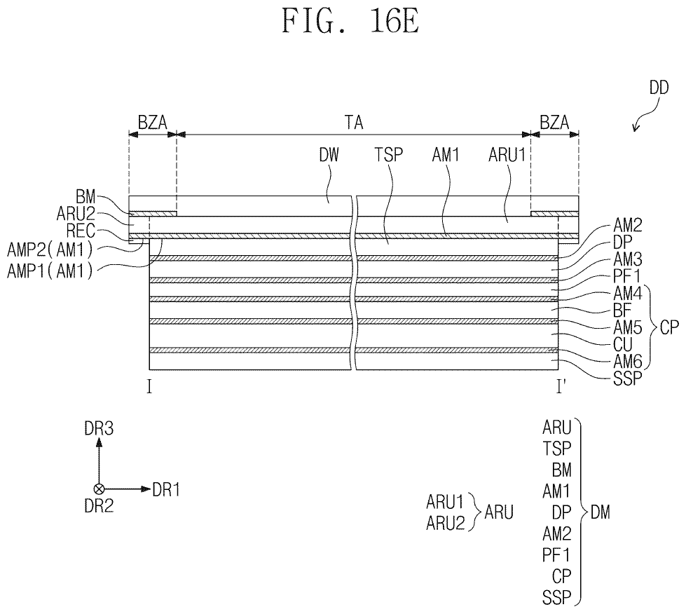

FIGS. 16A to 16E are cross-sectional views illustrating a portion of the method of manufacturing the display device DD, according to an embodiment. FIGS. 16A to 16E are cross-sectional views illustrating a portion of the method of manufacturing the display device DD of FIG. 10, according to an embodiment. The same reference numerals are used for the components described in FIG. 10, and a description thereof will be omitted.

In an embodiment and referring to FIGS. 16A and 16B, the display panel DP and the polarization unit ARU having the first adhesive layer AM1 directly disposed on the lower surface thereof and covering the display panel DP and the touch detection panel TSP on a plane may be prepared. The polarization unit ARU including the first polarization part ARU1 and the second polarization part ARU2 may be adhered to the upper surface of the touch detection panel TSP.

In an embodiment and referring to FIG. 16C, the first adhesive protection member REC may be formed on the lower surface of the first adhesive layer AM1. The first adhesive protection member REC may be formed on the lower surface of the second adhesive part AMP2 of the lower surface of the first adhesive layer AM1, which corresponds to the second polarization part ARU2. In this case, a resin having no adhesive force may be applied to the lower surface of the second adhesive part AMP2. The coated resin layer may prevent the lower surface of the second adhesive part AMP2 from being exposed to the outside. FIG. 16C illustrates that the first adhesive protection member REC is coated after the polarization unit ARU is adhered to the touch detection panel TSP, but the first adhesive protection member REC may be coated before the polarization unit ARU is adhered to the touch detection panel TSP. For example, after the first adhesive protection member REC is coated on the lower surface of the second adhesive part AMP2 of FIG. 13B, the polarization unit ARU may be adhered to the touch detection panel TSP.

In an embodiment and referring to FIGS. 16D and 16E, the light shielding pattern BM and the coated window DW may be formed on the polarization unit ARU. The light shielding pattern BM and the coated window DW may be formed in the same manner as that described with reference to FIGS. 13D and 13E.

FIGS. 17A to 17E are cross-sectional views illustrating a portion of the method of manufacturing the display device DD, according to an embodiment. FIGS. 17A to 17E are cross-sectional views illustrating a portion of the method of manufacturing the display device DD of FIG. 11, according to an embodiment. The same reference numerals are used for the components described in FIG. 11, and a description thereof will be omitted.

In an embodiment and referring to FIG. 17A, the display panel DP and the polarization unit ARU having the first adhesive layer AM1 disposed on the lower surface thereof and covering the display panel DP on a plane may be prepared. The protective film LAP may be attached onto the lower surface of the first adhesive layer AM1. The protective film LAP may be directly disposed on the lower surface of the first adhesive layer AM1 and may cover the lower surface of the polarization unit ARU. The protective film LAP may include the first protective film part LAP1 and the second protective film part LAP2 divided by the cutting line CL. Here, the first protective film part LAP1 may overlap the touch detection panel TSP, and the second protective film part LAP2 may not overlap the touch detection panel TSP.

In an embodiment and referring to FIGS. 17B and 17C, the first protective film part LAP1 (see FIG. 17A) defined inside the cutting line CL may be removed. After the first protective film part LAP1 (see FIG. 17A) is removed, the second protective film part LAP2 (see FIG. 17A) may serve as the second adhesive protection member APL. After the second protective film part LAP2 (see FIG. 17A) is removed, the polarization unit ARU may be adhered onto the touch detection panel TSP.

In an embodiment and referring to FIGS. 17D and 17E, the light shielding pattern BM and the coated window DW may be formed on the polarization unit ARU. The light shielding pattern BM and the coated window DW may be formed in the same manner as that described with reference to FIGS. 13D and 13E.

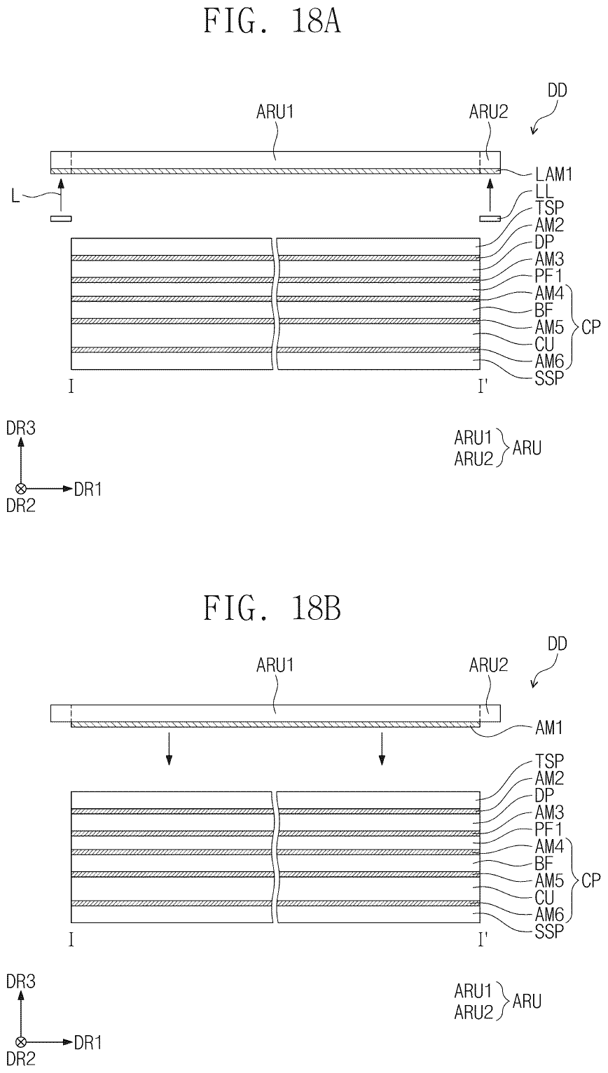

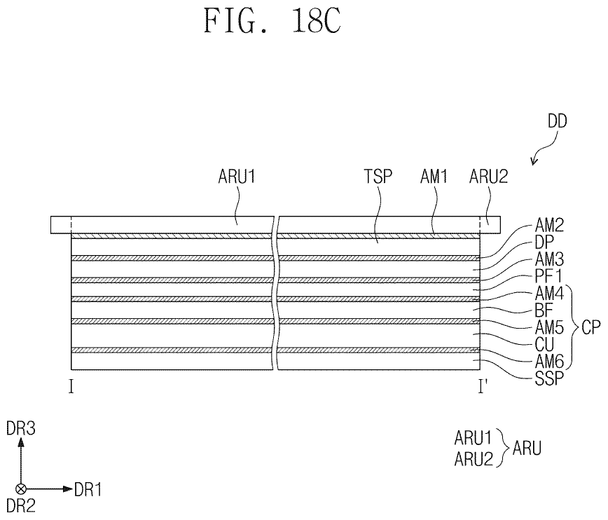

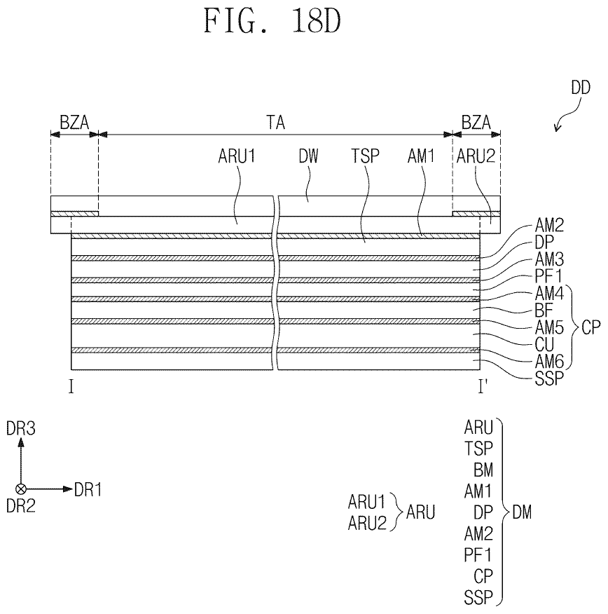

FIGS. 18A to 18D are cross-sectional views illustrating a portion of the method of manufacturing the display device DD, according to an embodiment. FIGS. 18A to 18D are cross-sectional views illustrating a portion of the method of manufacturing the display device DD of FIG. 12, according to an embodiment. The same reference numerals are used for the components described in FIG. 12, and a description thereof will be omitted.

In an embodiment and referring to FIG. 18A, the display panel DP and the polarization unit ARU having the preliminary first adhesive layer LAM1 directly disposed on the lower surface thereof and covering the display panel DP and the touch detection panel TSP on a plane may be prepared. A portion of the preliminary first adhesive layer LAM1, which does not overlap the touch detection panel TSP and corresponds to the second polarization part ARU2, may be removed using the laser beam “L” generated by the exposure device LL. However, as illustrated in FIG. 18A, the preliminary first adhesive layer LAM1 is disposed on the lower surface of the polarization unit ARU, the portion of the preliminary first adhesive layer LAM1 is not removed using the laser beam “L”, and the first adhesive layer AM1 (see FIG. 18B) having a size corresponding to the touch detection panel TSP may also be laminated on the lower surface of the polarization unit ARU. In this case, an operation of irradiating the laser beam “L” of FIG. 18A may be omitted.

Furthermore, in an embodiment, the portion of the preliminary first adhesive layer LAM1 is not removed using the laser beam “L”, but is attached to the upper surface of the touch detection panel TSP, and then is removed using the laser beam “L” generated by the exposure device LL, so that the first adhesive layer AM1 (see FIG. 18B) may be formed.

In an embodiment and referring to FIGS. 18B and 18C, the first adhesive layer AM1 of which a portion corresponding to the second polarization part ARU2 is removed may be adhered to the upper surface of the touch detection panel TSP. The first adhesive layer AM1 may be disposed only between the first polarization part ARU1 and the touch detection panel TSP and may not be exposed to the outside.

In an embodiment and referring to FIG. 18D, the light shielding pattern BM and the coated window DW may be formed on the polarization unit ARU. The light shielding pattern BM and the coated window DW may be formed in the same manner as that described with reference to FIGS. 13D and 13E.

In a display device DD according to an embodiment, a polarization unit may be expanded, and a light shielding pattern and a coated window may be formed on the expanded polarization unit. The expanded polarization unit may serve as a base when the light shielding pattern and the coated window are manufactured.

In an embodiment, as an adhesive protection member is disposed in a portion of a rear surface of the expanded polarization unit, to which an adhesive is exposed, the adhesive is directly exposed to the outside, and thus foreign substances may be prevented from adhering to the adhesive or the adhesive may be prevented from adhering to other components during a process.

Although the description has been made above with reference to embodiments of the invention, it may be understood that those skilled in the art or those having ordinary knowledge in the art may variously modify and change the invention without departing from the spirit and technical scope of the invention described herein and in the appended claims. Accordingly, the technical scope of the invention is not limited to the detailed description of the specification. Moreover, the embodiments or parts of the embodiments may be combined in whole or in part without departing from the scope of the invention.

What is claimed is:

1. A display device comprising:
a display panel including a display area and a non-display area surrounding the display area;
a polarization unit that includes a first polarization part overlapping the display panel on a plane and a second polarization part extending from the first polarization part and having an outer surface protruding further outward than an outer surface of the display panel, wherein the polarization unit is disposed on the display panel, and covers the display panel on a plane;
an adhesive layer that includes a first adhesive part disposed between the first polarization part and the display panel and a second adhesive part overlapping the second polarization part and wherein the adhesive layer is directly disposed on a lower surface of the polarization unit;
an adhesive protection member directly disposed on a lower surface of the second adhesive part;
a light shielding pattern directly disposed on the polarization unit and corresponding to the non-display area; and
a coated window directly disposed on the polarization unit and the light shielding pattern and including a resin material cured by laser irradiation.

2. The display device of claim 1, wherein the adhesive protection member is a part of a protective film of the polarization unit.

3. The display device of claim 1, wherein the adhesive protection member is a resin coated layer.

4. The display device of claim 1, wherein the second polarization part does not overlap the display panel.

5. The display device of claim 1, wherein one side of the polarization unit protrudes further outward than one side of the display panel, wherein the one side of the polarization unit is disposed adjacent to the one side of the display panel.

6. The display device of claim 1, wherein one side of the polarization unit and one side of the coated window are aligned with each other on a cross section, wherein the one side of the coated window is disposed adjacent the one side of the polarization unit.

7. The display device of claim 1, wherein a lower surface of the adhesive layer is covered by the display panel and the adhesive protection member.

8. The display device of claim 1, wherein the light shielding pattern overlaps the second polarization part and a portion of the first polarization part.

9. The display device of claim 1, wherein one side of the display panel and one side of the adhesive protection member are in contact with each other, wherein the one side of the display panel is disposed adjacent to the one side of the adhesive protection member.

10. The display device of claim 1, wherein the display panel includes a non-bending area and a bending area and wherein the bending area is extending from and is bent from a distal end of the non-bending area, and
wherein the display device further includes a bending protection layer disposed on the display panel and bent together with the bending area.

11. The display device of claim 1, further comprising:
a protective panel that includes a barrier layer shielding a light beam and a cushion layer absorbing an external impact, wherein the protective panel is disposed on a lower surface of the display panel, and protects the display panel.

12. A display device comprising:
a display panel including a display area and a non-display area surrounding the display area;
a touch detection panel disposed on the display panel and configured to detect an input signal;
a polarization unit that includes a first polarization part overlapping the touch detection panel on a plane and a second polarization part extending from the first polarization part and having an outer surface protruding further outward than an outer surface of the touch detection panel, wherein the polarization unit is disposed on the touch detection panel, and covers the display panel and the touch detection panel on a plane;
an adhesive layer that includes a first adhesive part disposed between the first polarization part and the touch detection panel and a second adhesive part overlapping the second polarization part, wherein the adhesive layer is directly disposed on a lower surface of the polarization unit;
an adhesive protection member directly disposed on a lower surface of the second adhesive part;
a light shielding pattern directly disposed on the polarization unit and corresponding to the non-display area; and
a coated window directly disposed on the polarization unit and the light shielding pattern and including a resin material cured by laser irradiation.

13. The display device of claim 12, wherein a lower surface of the adhesive layer is covered by the touch detection panel and the adhesive protection member.

14. The display device of claim 12, further comprising:
a circuit board overlapping the non-display area, wherein the circuit board is bent and includes one end which is disposed on a front surface of the display panel and an other end which is disposed on a rear surface of the display panel,
wherein the display panel is rigid.

15. The display device of claim 12, wherein an outer surface of the adhesive layer, an outer surface of the adhesive protection member, and an outer surface of the polarization unit are aligned with each other on a cross section.

16. A method of manufacturing a display device, the method comprising:
preparing a display panel, wherein the display panel includes a display area and a non-display area surrounding the display area, and a polarization unit having an adhesive layer directly disposed on a lower surface thereof and covering the display panel on a plane;
forming an adhesive protection member on a lower surface of the adhesive layer;
adhering a polarization unit to the display panel, wherein the polarization unit includes a first polarization part overlapping the display panel on a plane and a second polarization part extending from the first polarization part and having an outer surface that protrudes further outward than an outer surface of the display panel;
forming a light shielding pattern, wherein the light shielding pattern is directly disposed on the polarization unit and corresponds to the non-display area; and
forming a coated window, wherein the coated window is directly disposed on the polarization unit and the light shielding pattern, and includes a resin material cured by laser irradiation.

17. The method of claim 16, wherein in the forming of the adhesive protection member on the lower surface of the adhesive layer, a portion of the lower surface of the adhesive layer, which corresponds to the second polarization part, is resin-coated.

18. The method of claim 16, wherein the forming of the adhesive protection member on the lower surface of the adhesive layer includes:
attaching a protective film, wherein the protective film includes a first protective film part and a second protective film part divided by a cutting line, is directly disposed on the lower surface of the adhesive layer, and covers a lower surface of the polarization unit; and
removing the first protective film part, wherein the first protective film part is defined inside the cutting line.

19. The method of claim 18, wherein the first protective film overlaps the display panel, and the second protective film does not overlap the display panel.

20. The method of claim 16, wherein the forming of the coated window includes:
applying a resin material onto the polarization unit; and
curing the applied resin material.
